(19) United States
(12) Patent Application Publication
(10) Pub. No.: US 2026/0354049 A1
(43) Pub. Date: Nov. 5, 2026

(54) PHASE-CHANGE MEMORY DEVICE WITH THERMAL PROTECTION LAYERS AND METHOD OF FORMING THE SAME

(71) Applicant: Taiwan Semiconductor Manufacturing Company Limited, Hsinchu (TW)

(72) Inventors: Hung-Ju Li, Hsinchu City (TW); Pei-Shan Hsieh, Hsinchu (TW); Rutu Amit Patel, Hsinchu (TW); Kuo-Pin Chang, Zhubei City (TW); Yu-Wei Ting, Taipei City (TW); Chang-Chih Huang, Taichung (TW); Hsin Fu Lin, Hsinchu (TW); Kuo-Ching Huang, Hsinchu City (TW)

(21) Appl. No.: 19/195,956

(22) Filed: May 1, 2025

(51) Int. Cl. H10N 70/00; H10B 63/10; H10N 70/20

(52) U.S. Cl. CPC H10N 70/8616; H10B 63/10; H10N 70/063; H10N 70/231; H10N 70/8265

(57) ABSTRACT

A device structure may be provided by: forming via bottom electrodes in a dielectric material layer; depositing a layer stack including a phase-change material layer, a thermal protection material layer comprising a thermal protection material having a first thermal conductivity, and a top electrode material layer comprising a top electrode material having a second thermal conductivity over the dielectric material layer, wherein the second thermal conductivity is greater than the first thermal conductivity; and patterning the layer stack into a plurality of plate stacks. Each of the plate stacks comprises a respective phase-change material portion, a respective thermal protection plate, and a respective top electrode, and is formed over a respective one of the via bottom electrodes.

### BACKGROUND

Phase-change material (PCM) devices may be used for memory-based computing applications due to their scalability and non-volatility. PCM devices utilize the phase-changing properties of a PCM material between an amorphous state and a crystalline state to store information. The switching between the amorphous state and the crystalline state is achieved through the application of electrical pulses, which may induce localized heating and cooling of the phase-change material. The amorphous state exhibits higher electrical resistance than the crystalline state, allowing for the representation of different logic states. The thermal management of a phase-change material portion during programming affects the microscopic structures of the phase-change material, and thus, affects the performance and reliability of the PCM devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of a first embodiment structure after formation of field effect transistors, metal interconnect structures, and dielectric material layers according to a first embodiment of the present disclosure.

FIG. 2 is a vertical cross-sectional view of the first embodiment structure after formation of via bottom electrodes according to the first embodiment of the present disclosure.

FIG. 3 is a vertical cross-sectional view of the first embodiment structure after formation of a continuous layer stack including a bottom electrode material layer, a phase-change material layer comprising a phase-change material, a thermal protection material layer, a top electrode material layer, and a hardmask material layer according to the first embodiment of the present disclosure.

FIG. 4 is a vertical cross-sectional view of the first embodiment structure after patterning the hardmask material layer, the top electrode material layer, the thermal protection material layer, the phase-change material layer, and the bottom electrode material layer into stacks of an in-process hardmask plate, an in-process top electrode, an in-process thermal protection plate, an in-process phase-change material portion, and an in-process plate bottom electrode according to the first embodiment of the present disclosure.

FIG. 5 is a vertical cross-sectional view of the first embodiment structure after deposition of a spacer material layer according to the first embodiment of the present disclosure.

FIG. 6 is a vertical cross-sectional view of the first embodiment structure after an anisotropic etch process that etches horizontally-extending portions of the spacer material layer according to the first embodiment of the present disclosure.

FIG. 7A-7C are sequential top-down views of a region of the first embodiment structure during patterning of the in-process stacks into stacks of a hardmask plate, a top electrode, a thermal protection plate, a phase-change material portion, and a plate bottom electrode according to the first embodiment of the present disclosure.

FIG. 8 is a vertical cross-sectional view of the first embodiment structure after formation of the stacks of a hardmask plate, a top electrode, and a phase-change material portion according to the first embodiment of the present disclosure.

FIG. 9 is a vertical cross-sectional view of the first embodiment structure after formation of an encapsulation dielectric layer and additional metal interconnect structures according to the first embodiment of the present disclosure.

FIG. 10 is a vertical cross-sectional view of a second embodiment structure after patterning of the in-process stacks into stacks of a hardmask plate, a top electrode, a thermal protection plate, a phase-change material portion, and a plate bottom electrode according to a second embodiment of the present disclosure.

FIG. 11 is a vertical cross-sectional view of the second embodiment structure after removal of the photoresist layer according to the second embodiment of the present disclosure.

FIG. 12 is a vertical cross-sectional view of the second embodiment structure after formation of an encapsulation dielectric layer and additional metal interconnect structures according to the second embodiment of the present disclosure.

FIG. 13 is a vertical cross-sectional view of the third embodiment structure after formation of a continuous layer stack including a phase-change material layer comprising a phase-change material, a thermal protection material layer, a top electrode material layer, and a hardmask material layer according to the third embodiment of the present disclosure.

FIG. 14 is a vertical cross-sectional view of the third embodiment structure after formation of the stacks of a hardmask plate, a top electrode, and a phase-change material portion according to the third embodiment of the present disclosure.

FIG. 15 is a vertical cross-sectional view of the third embodiment structure after removal of a photoresist layer according to the third embodiment of the present disclosure.

FIG. 16 is a vertical cross-sectional view of the third embodiment structure after formation of an encapsulation dielectric layer and additional metal interconnect structures according to the third embodiment of the present disclosure.

FIG. 17A is a vertical cross-sectional view of a comparative exemplary phase-change memory cell that does not use any thermal protection plate in a high resistance state.

FIG. 17B is a vertical cross-sectional view of an exemplary phase-change memory cell according to an embodiment of the present disclosure in a high resistance state.

FIG. 18 is a first flowchart that illustrates general processing steps for manufacturing a device structure according to embodiments of the present disclosure.

FIG. 19 is a second flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element in instances in which the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Unless explicitly stated otherwise, each material portion is presumed to have a homogeneous material composition throughout.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3.0, and/or 10, and/or 100, and/or 1,000. As used herein, a first surface and a second surface are “vertically coincident” with each other if the second surface overlies or underlies the first surface and there exists a vertical plane or a substantially vertical plane that includes the first surface and the second surface. A vertical plane is a two-dimensional manifold containing a contiguous set of an uncountable infinity of vertical lines, and has a uniform one-dimensional horizontal cross-sectional shape that is invariant under translation along a vertical direction. The vertical plane may be a Euclidian plane if the uniform one-dimensional horizontal cross-sectional shape is a line, or may be a non-Euclidian plane if the uniform one-dimensional shape is not a line. A substantially vertical line is a straight line that deviates from a vertical direction by an angle less than 5 degrees. A substantially vertical plane is a two-dimensional manifold containing a contiguous set of an uncountable infinity of substantially vertical lines and/or vertical lines.

Phase-change memory (PCM) devices provide non-volatile storage and multi-level cell capabilities for memory-based computing applications. PCM devices utilize programmable microstructural changes between an amorphous state and a crystalline states in phase-change materials to store information. The switching between the amorphous state and the crystalline state is achieved through application of electrical pulses, which induce localized heating and cooling of the phase-change material. The amorphous state exhibits higher electrical resistance compared to the crystalline state. The differences in the electrical resistance between the amorphous state and the crystalline state allow representation of different logic states.

The thermal management within a phase-change material portion during programming impacts the performance and reliability of a phase-change memory cell. Exemplary metrics for measuring the performance include the difference in the resistance of the phase-change memory cell between the amorphous state and the crystalline state, the energy that is required to program the phase-change memory cell into the amorphous state or into the crystalline state, etc. Exemplary metrics for measuring the reliability include the statistical distribution of post-programming resistance for the amorphous state, the statistical distribution of post-programming resistance for the crystalline state, the leakage current between a phase-change material device and adjacent devices, structural damage that may occur around a phase-change material device after repeated programming operations, etc.

According to an aspect of the present disclosure, a thermal protection plate is disposed between a phase-change material portion and a top electrode of a phase-change memory cell. The thermal protection plate enhances heat retention within the phase-change material portion, and increases lateral heat transfer relative to the vertical heat transfer into the top electrode. Heat may be retained more uniformly within the phase-change material portion during programming, and the programming operations may be performed with less energy. Further, the vertical thickness of an amorphous phase-change material portion in a high-resistance state increases near the sidewalls of the phase change material portion, and the leakage current through the amorphous phase-change material portion may be reduced to provide improved device characteristics.

The thermal protection plate comprises a material having a lower thermal conductivity compared to the thermal conductivity of the material of the top electrode material. The lower thermal conductivity of the thermal protection plate restricts heat dissipation from the phase-change material to the top electrode. Thus, the thermal protection plate induces more uniform temperature distribution within the phase-change material portion during programming operations, and allows for more consistent switching behavior and improved reliability of the PCM device of the present disclosure. The various embodiments of the present disclosure are now described with reference to accompanying drawings.

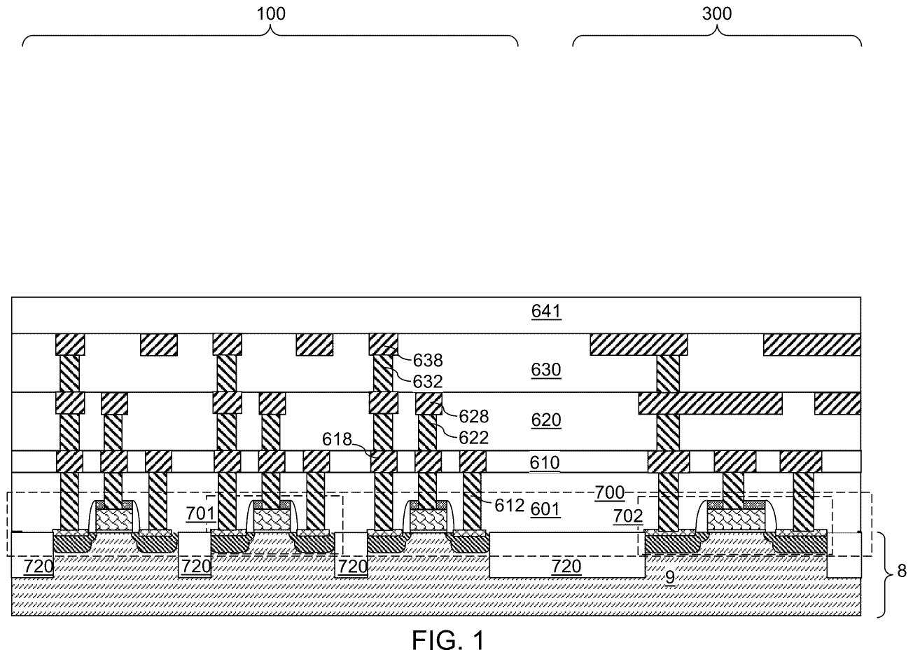

Referring to FIG. 1, a first embodiment structure according to the present disclosure is illustrated. The first embodiment structure includes a substrate 8, which may be a semiconductor substrate, such as a commercially available silicon substrate. The substrate 8 may include a semiconductor material layer 9 at least in an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720.

Semiconductor devices 700 may be formed on the semiconductor material layer 9. The semiconductor devices 700 may comprise complementary metal-oxide-semiconductor (CMOS) transistors and optionally additional semiconductor devices (such as resistors, diodes, capacitor structures, etc.). The semiconductor devices 700 may comprise programming transistors 701 that are formed in a memory array region 100, and peripheral transistors 702 that are formed in a peripheral region 300. Each field effect transistor (701, 702) may comprise a source region, a drain region, a channel region, a gate dielectric, and a gate electrode. In one embodiment, the channel region may comprise a portion of the semiconductor material layer 9, and may comprise a single crystalline semiconductor material. Each of the programming transistors 701 may be configured to provide a set of programming pulses for a respective phase-change memory cell to be subsequently formed. The peripheral transistors 702 may be formed as components of a peripheral circuit that controls the operation of the programming transistors 701, and interfaces with an input/output (I/O) circuit (not illustrated).

In one embodiment, the substrate 8 may include a single crystalline silicon substrate, and the field effect transistors (701, 702) may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0 ×10⁵ S/cm upon suitable doping with an electrical dopant.

Various metal interconnect structures embedded within dielectric material layers may be subsequently formed over the substrate 8 and the semiconductor devices. In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the semiconductor devices 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. An additional dielectric material layer, which is herein referred to as a lower fourth interconnect-level dielectric material layer 641 may be formed over the third interconnect-level dielectric material layer 630.

Each of the dielectric material layers (601, 610, 620, 630, 641) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure. Although FIG. 1 illustrates a set number of dielectric material layers and metal interconnect structures, more or less number of layers and structures are within the contemplated scope of disclosure.

Generally, semiconductor devices (such as field effect transistors (701, 702)) may be formed on a substrate 8, and metal interconnect structures (612, 618, 622, 628, 632, 638) and dielectric material layers (601, 610, 620, 630, 641) over the semiconductor devices. The metal interconnect structures (612, 618, 622, 628, 632, 638) may be formed in the dielectric material layers (601, 610, 620, 630, 641), and may be electrically connected to the semiconductor devices. In one embodiment, programming transistors 701 may be formed on a substrate 8. The metal interconnect structures (612, 618, 622, 628, 632, 638) may be configured to be electrically connected to heater elements of phase-change memory cells to be subsequently formed. The metal interconnect structures (612, 618, 622, 628, 632, 638) are herein referred to as lower-level metal interconnect structures (612, 618, 622, 628, 632, 638), and the interconnect-level dielectric material layers (601, 610, 620, 630, 641) are herein referred to as lower-level dielectric material layers (601, 610, 620, 630, 641).

According to an aspect of the present disclosure, the programming transistors 701 may be configured to program a respective one of the phase-change memory cells into at least two different resistive states, and preferably into at least three different resistive states, and more preferably into at least four different resistive states. The programming of each phase-change memory cell into different resistive states may be effected by selecting a pulse pattern from a set of pre-programmed pulse patterns that each programming transistor 701 may apply.

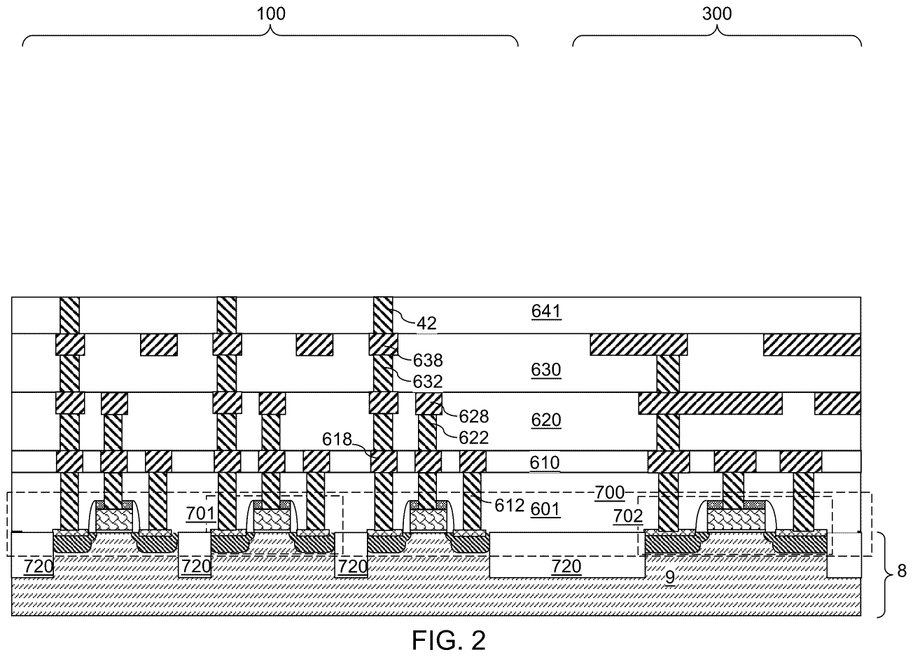

Referring to FIG. 2, via cavities may be formed through a topmost dielectric material layer (such as the lower fourth interconnect-level dielectric material layer 641) in the first embodiment structure. Each cavity may be formed over a respective one of the underlying metal interconnect structures (such as a subset of the third metal line structures 638) so that top surface segments of the underlying metal interconnect structures are physically exposed. The dielectric material layer, through which the cavities are formed, comprises a heat-resistant dielectric material such as undoped silicate glass or a doped silicate glass. The thickness of the dielectric material layer may be in a range from 20 nm to 100 nm, although lesser or greater thicknesses may also be used. In one embodiment, the cavities may be formed as via cavities having a respective lateral dimension (such as the diameter) in a range from 20 nm to 100 nm, although lesser or greater lateral dimensions may also be used.

At least one metallic material may be deposited in the cavities through the dielectric material layer. The at least one metallic material may comprise a combination of a metallic liner material and a metallic fill material. The metallic liner material may be a conductive metallic nitride material such as TiN, and the metallic fill material may comprise a high-conductivity metal such as tungsten. Excess portions of the at least one metallic material may be removed from above the horizontal plane including the top surface of the dielectric material layer (such as the lower fourth interconnect-level dielectric material layer 641) by performing a planarization process, which may comprise a recess etch process and/or a chemical mechanical polishing process. Each remaining portion of the at least one metallic material constitutes a via bottom electrode 42. In one embodiment, the via bottom electrodes 42 may be formed as metallic via structures each having a respective planar bottom surface, a respective planar top surface, and a respective set of at least one straight sidewall. Generally, via bottom electrodes 42 are formed within a dielectric material layer (such as a lower fourth interconnect-level dielectric material layer 641).

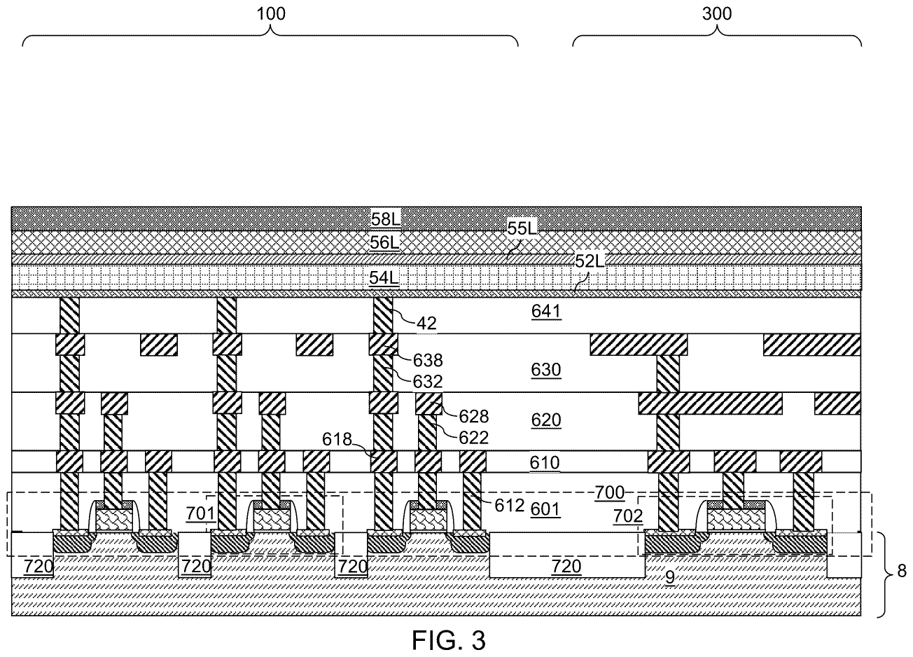

Referring to FIG. 3, a continuous layer stack (52L, 54L, 55L, 56L, 58L) including a bottom electrode material layer 52L, a phase-change material layer 54L comprising a phase-change material, a thermal protection material layer 55L, a top electrode material layer 56L, and a hardmask material layer 58L may be deposited over the top surface of the dielectric material layer (such as the lower fourth interconnect-level dielectric material layer 641) that embeds the via bottom electrodes 42.

The bottom electrode material layer 52L comprises a conductive material having a first electrical conductivity greater than 1.0×10⁵ S/m. In one embodiment, the bottom electrode material layer 52L comprises a first metallic nitride material, which may be a stoichiometric or near-stoichiometric metallic nitride material. For example, the bottom electrode material layer 52L may comprise TaN, TiN, WN, and/or MoN. In one embodiment, the electrical conductivity of the metallic material of the bottom electrode material layer 52L may be in a range from 1.0×10⁵ S/m to 1.0×10⁷ S/m. The thickness of the bottom electrode material layer 52L is selected such that patterned portions of the bottom electrode material layer 52L may provide electrical resistance during operation of phase memory cells to be subsequently formed. For example, the thickness of the bottom electrode material layer 52L may be in a range from 1 nm to 20 nm, such as from 2 nm to 4 nm, although lesser or greater thicknesses may also be used. The bottom electrode material layer 52L may be deposited by chemical vapor deposition or physical vapor deposition.

The phase-change material layer 54L comprises, and/or consists essentially of, a phase-change material. As used herein, a “phase-change material” refers to a material having at least two different phases providing different resistivity. A phase-change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase-change material amorphous in a first part of a programming process. The second part of the programming process includes control of the cooling rate of the phase-change material. In embodiments in which rapid quenching occurs, the phase-change material may cool into an amorphous high resistivity state. In embodiments in which slow cooling occurs, the phase-change material may cool into a crystalline low resistivity state.

Exemplary phase-change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. In one embodiment, the phase-change material of the phase-change material layer 54L may comprise a doped GST compound such as N-doped GST, Si-doped GST, C-doped GST, Ge-doped GST, Ru-doped GST, or Al-doped GST, or a doped GeTe compound such as N-doped GeTe, Si-doped GeTe, C-doped GeTe, or Ge-doped GeTe. The phase-change material layer 54L may be deposited by physical vapor deposition. The thickness of the phase-change material layer 54L may be in a range from 10 nm to 150 nm, such as from 20 nm to 100 nm, although lesser and greater thicknesses may also be used. In one embodiment, the phase-change material of the phase-change material layer may be selected such that the electrical conductivity of the amorphous phase of the phase-change material is in a range from 1.0×10⁻⁶ S/m to 1.0×10⁻¹ S/m, while the electrical conductivity of the crystalline phase of the phase-change material is in a range from 1.0×10¹ S/m to 1.0×10⁵ S/m.

The thermal protection material layer 55L comprises a thermal protection material having a first thermal conductivity. According to an aspect of the present disclosure, the first thermal conductivity is lower than the thermal conductivity of a top electrode material to be subsequently used. The thermal protection material layer 55L is configured to reduce heat dissipation from the underlying phase-change material, thereby improving thermal efficiency and enhancing the reliability of phase transitions. In one embodiment, the first thermal conductivity may be in a range from 1 W/m·K to 50 W/m·K.

Generally, the thermal protection material layer 55L comprises a single material layer or a layer stack of a plurality of material layers each composed of a material selected to provide thermal and/or electrical impedance relative to the top electrode layer 56L that is subsequently formed. In one embodiment, the thermal protection material layer 55L may be formed as a multilayer stack of two or more layers having different compositions, thicknesses, or dopant profiles. The number of layers in the layer stack may be 2 or more. The materials of the thermal protection layer 55L may include, but are not limited to, TiN, TaN, WN, AlN, C-WN (i.e., a carbon-tungsten nitride alloy), C-AlN (a carbon aluminum-nitride alloy), doped or undoped metallic nitrides (e.g., doped TiN, doped TaN, doped WN, doped AlN), or partially oxidized variants thereof.

Additionally, metals such as Cu, Al, Au, Ag, Pt, and W may also be used as thermal protection materials, provided they are compositionally or functionally distinct from the top electrode material of the top electrode layer 56L that is subsequently formed. For example, metals such as Cu, Al, Au, Ag, Pt, and W may be used in the thermal protection layer 55L in embodiments in which they are doped, layered, alloyed, or otherwise modified to achieve higher thermal resistivity and/or higher electrical resistivity than the material of the top electrode layer 56L that is subsequently formed. In all embodiments, the thermal protection material layer 55L may be compositionally different and/or less conductive (electrically or thermally) than the material of the top electrode layer 56L in order to promote lateral current spreading and thermal decoupling. In some cases, the thermal protection material layer 55L and the top electrode layer 56L may be formed using similar base materials, but the thermal protection material layer 55L and the top electrode layer 56L may differ in microstructure, doping, layering configuration, or interface treatments, such that their functional properties (e.g., thermal resistance or electrical resistivity) remain distinct.

The thermal protection material layer 55L may be formed by depositing a metallic compound material comprising a nitride of a first metal. In one embodiment, the first metal is selected from titanium (Ti), tantalum (Ta), tungsten (W), or aluminum (Al). In one embodiment, the thermal protection material layer 55L comprises a doped metal nitride material that includes dopant atoms selected from boron (B), carbon (C), aluminum (Al), and oxygen (O). The incorporation of dopant atoms into the thermal protection material layer 55L reduces its thermal conductivity relative to an undoped metal nitride material while optionally increasing its electrical conductivity. The thermal protection material layer 55L may be formed by depositing an undoped metal nitride layer and subsequently introducing dopant atoms via implantation or by converting the undoped metal nitride layer into a metal oxynitride layer through partial oxidation. The thickness of the thermal protection material layer 55L may range from 1 nm to 100 nm, although greater or lesser thicknesses may be used depending on design requirements.

The thermal protection material layer 55L may be formed using various deposition methods depending on the desired material composition and integration requirements. In one embodiment, the thermal protection material layer 55L is deposited using physical vapor deposition (PVD), such as sputtering, wherein a metal nitride target is bombarded with high-energy particles to deposit a conformal metal nitride layer. Alternatively, chemical vapor deposition (CVD) may be used to deposit the thermal protection material layer 55L, particularly when a highly uniform and conformal layer is required. For example, metal-organic CVD (MOCVD) may be used to deposit titanium nitride (TiN) or tungsten nitride (WN) using precursor gases such as tetrakis(dimethylamino)titanium (TDMAT) or tungsten hexafluoride (WF₆) in combination with ammonia (NH₃). In another embodiment, atomic layer deposition (ALD) may be utilized to precisely control the thickness and composition of the thermal protection material layer 55L, enabling uniform doping incorporation during layer growth.

In one embodiment, the dopant atoms incorporated into the thermal protection material layer 55L may be introduced either during deposition or as a post-deposition modification. In one embodiment, in-situ doping is performed during CVD or ALD, where gaseous dopant precursors such as boron trichloride (BCl₃), methane (CH₄) for carbon doping, or trimethylaluminum (TMA) for aluminum doping are introduced into the deposition chamber along with the metal nitride precursor. In another embodiment, dopant atoms are introduced into the thermal protection material layer 55L via ion implantation, wherein high-energy ions of boron (B), carbon (C), aluminum (Al), silicon (Si), germanium (Ge), nitrogen (N), or oxygen (O) may be implanted into an undoped metal nitride layer. The implanted layer may then be subjected to annealing at temperatures between 400 °C and 800 °C in a nitrogen or argon ambient to activate the dopants and restore crystalline order.

In one embodiment, the thermal protection material layer 55L may also be modified through partial oxidation to form a metal oxynitride, which may further reduce the thermal conductivity of the thermal protection material layer 55L. In one embodiment, the thermal protection material layer 55L may be first deposited as an undoped metal nitride layer and then subjected to a controlled oxidation process using an oxygen-containing plasma or thermal annealing in an oxygen-rich atmosphere. For example, a remote plasma oxidation (RPO) process may be used to introduce oxygen atoms into the metal nitride matrix, forming a TiON or WN(O) layer. This modification further enhances the thermal insulating properties of the thermal protection material layer 55L while maintaining sufficient electrical conductivity.

The atomic species and the concentration the dopant atoms may be selected to optimize the electrical and thermal properties of the thermal protection material layer 55L. In one embodiment, the atomic concentration of dopant species is in the range of 0.1 atomic percent to 20 atomic percent, although higher or lower concentrations may be used depending on the application. Boron doping, for instance, may introduce additional phonon scattering centers, reducing thermal conductivity while slightly increasing electrical resistivity. Carbon doping may enhance the mechanical hardness and chemical stability while further suppressing heat conduction of the thermal protection material layer 55L. Aluminum doping may enhance oxidation resistance while modifying electronic properties, and oxygen incorporation forms a partially insulating layer that increases thermal resistance.

The thermal protection material layer 55L may be integrated into the phase-change memory structure such that it enhances the efficiency of the thermal profile within the memory cell. By reducing heat dissipation into the surrounding materials, the thermal protection material layer 55L provides enhanced precision control over the phase-change process, leading to improved endurance and lower power consumption. The use of optimized metal nitrides and doped variants ensures that the thermal protection material layer 55L meets the necessary electrical and structural requirements while contributing to the scalability of phase-change memory technologies.

In one embodiment, dopant atoms within a doped metal nitride material comprise atoms that reduce the thermal conductivity of the thermal protection material, i.e., provide a thermal protection material having a lower thermal conductivity compared to the material prior to doping. Such dopant atoms introduce lattice distortions and phonon scattering centers within the metal nitride material, thereby impeding heat flow and decreasing thermal conductivity. Additionally, depending on the nature of the dopant, the electrical conductivity of the doped metal nitride may either increase or decrease, depending on whether the dopant provides additional charge carriers or acts as a scattering center for electrons. In some embodiments, dopants may be selected from boron (B), carbon (C), aluminum (Al), silicon (Si), germanium (Ge), nitrogen (N), and/or oxygen (O). The incorporation of the dopants modifies the crystalline or amorphous structure of the metal nitride material, introducing localized defect sites that disrupt phonon transport and modify electrical conduction pathways. As a result, the thermal conductivity of the doped thermal protection material may be reduced relative to its undoped counterpart, and its electrical conductivity may be tuned according to the selection of dopant species.

In one embodiment, the conductive material that is formed by a combination of a deposition of a metallic material and implantation of at least one dopant species may be non-stoichiometric. In an illustrative example, the metallic material may be selected from TiN, TaN, WN, AlN, C-WN, C-AlN, Cu, Al, Au, Ag, Pt, and W, and the at least one dopant species may be selected from boron (B), carbon (C), aluminum (Al), silicon (Si), germanium (Ge), nitrogen (N), and/or oxygen (O). In this case, the atomic percentage of the at least one dopant species is selected to be sufficient to reduce the thermal conductivity of the implanted metallic material relative to the thermal conductivity of the unimplanted metallic material. For example, the thermal conductivity of the implanted metallic material may be in a range from 0.0001 times the thermal conductivity of the unimplanted metallic material to 0.8 times the thermal conductivity of the unimplanted metallic material. In a preferred embodiment, the thermal conductivity of the implanted metallic material may be in a range from 0.001 times the thermal conductivity of the unimplanted metallic material to 0.3 times the thermal conductivity of the unimplanted metallic material.

In one embodiment, the thermal protection material layer 55L comprises, and/or consists essentially of, a material selected from titanium nitride (TiN), tantalum nitride (TaN), tungsten nitride (WN), aluminum nitride (AlN), carbon-doped tungsten nitride (C-WN), carbon-doped aluminum nitride (C-AlN), or metal-nitride compounds (Metal-N). The metal-nitride compounds may include a metal nitride material that is selected from nitrides of titanium (Ti), tantalum (Ta), tungsten (W), or aluminum (Al). The nitride material may be further modified by doping with an element selected from boron (B), carbon (C), aluminum (Al), silicon (Si), germanium (Ge), nitrogen (N), and/or oxygen (O). The doped metal nitride may also include oxidized variants of the base nitride material. The thickness of the thermal protection material layer 55L may range from 1 nm to 100 nm. Such a thickness may provide the thermal protection and enhancements while not impacting the overall size of the structure. Variations in thickness may be used to achieve specific thermal and electrical properties. The thermal protection material layer 55L may be deposited using physical vapor deposition (PVD), chemical vapor deposition (CVD), atomic layer deposition (ALD), or sputtering methods. The deposition process may regulate film thickness and uniformity.

In one embodiment, carbon (C) doping may be introduced into the thermal protection material to reduce thermal conductivity while enhancing electrical conductivity. Carbon doping reduces thermal conductivity by introducing phonon scattering sites within the metal nitride lattice, thereby impeding heat transport. This effect is observed in materials such as carbon-doped tungsten nitride (C-WN) and carbon-doped aluminum nitride (C-AlN), in which phonon scattering increases due to lattice distortions and defect formation. In contrast, carbon doping may increase electrical conductivity in certain metal nitrides by altering the electronic band structure and providing additional free carriers. For example, C-doped TiN or WN may exhibit higher electrical conductivity than their undoped counterparts due to the formation of metallic bonding states. Thus, in some embodiments, carbon doping may be used to achieve a balance between reduced thermal conductivity and enhanced electrical conductivity for the thermal protection material.

In another embodiment, aluminum (Al) doping may be incorporated into the thermal protection material layer 55L to modify both its thermal and electrical properties. Aluminum doping generally reduces thermal conductivity by introducing substitutional disorder in materials such as tungsten nitride (WN) or tantalum nitride (TaN), which increases phonon scattering. However, in aluminum nitride (AlN) itself, aluminum doping may increase thermal conductivity in certain conditions by improving crystallinity and reducing defect scattering. Regarding electrical conductivity, Al doping generally reduces electrical conductivity in metal nitrides by introducing charge carrier scattering and disrupting conduction pathways. For example, Al-doped WN or TiN typically exhibits lower electrical conductivity than undoped WN or TiN due to the altered electronic band structure. Thus, in some embodiments, aluminum doping may be utilized to tailor the thermal protection material for applications where reduced heat dissipation and controlled electrical resistance are desired.

In one embodiment, boron (B) doping may be applied to metal nitrides to achieve a reduction in thermal conductivity while also reducing electrical conductivity. Boron doping reduces thermal conductivity by introducing additional phonon scattering sites, which impede heat flow within the crystal lattice. For example, boron-doped titanium nitride (B-TiN) and boron-doped tungsten nitride (B-WN) have been observed to exhibit lower thermal conductivity than their undoped counterparts due to increased defect scattering. Similarly, boron doping decreases electrical conductivity by acting as an electron scattering center, disrupting electron mobility and increasing electrical resistivity. As an example, B-doped TiN exhibits lower electrical conductivity than undoped TiN due to the increased resistivity caused by boron incorporation. Accordingly, in some embodiments, boron doping may be used in the thermal protection material to enhance heat retention while also contributing to increased electrical resistance to reduce leakage currents in phase-change memory devices.

In another embodiment, oxygen (O) doping may be used to reduce both thermal conductivity and electrical conductivity of the thermal protection material. Oxygen incorporation into metal nitrides such as tantalum nitride (TaN) or tungsten nitride (WN) results in partial oxidation, leading to increased phonon scattering and reduced thermal transport efficiency. The formation of localized oxygen-related defects disrupts phonon pathways, decreasing thermal conductivity. Additionally, oxygen doping strongly decreases electrical conductivity, as oxygen creates localized insulating regions within the metal nitride structure, thereby reducing free charge carrier density. For example, oxygen-doped tantalum nitride (TaN-Ox) exhibits lower electrical conductivity than undoped TaN due to the formation of insulating oxide phases. In some embodiments, oxygen doping may be used to engineer the thermal protection material for applications requiring strong thermal insulation and controlled electrical resistivity.

In some embodiments, the selection of dopant type and concentration may be tailored to achieve a desired balance between thermal and electrical properties. The extent to which doping impacts thermal and electrical conductivity may depend on factors such as dopant concentration, deposition method, and post-deposition processing conditions. In some implementations, doping levels may range from approximately 0.1 atomic percent to 20 atomic percent, although greater or lesser doping concentrations may also be used depending on the specific material system and device application. Additionally, in one embodiment, the doped thermal protection material may be deposited using physical vapor deposition (PVD), chemical vapor deposition (CVD), atomic layer deposition (ALD), or other known deposition methods. By selecting dopant species and doping levels, the thermal protection material may be optimized to enhance the performance of phase-change memory devices by reducing thermal dissipation and controlling electrical resistivity.

In one embodiment, the thermal protection material of the thermal protection material layer 55L comprises, and/or consists essentially of, titanium nitride (TiN), and the top electrode material of the top electrode material layer 56L comprises, and/or consists essentially of, copper (Cu). Titanium nitride (TiN) has a thermal conductivity of approximately 30 W/m·K, which is lower than that of copper, thereby effectively reducing heat dissipation and enhancing thermal retention within the phase-change material. TiN also exhibits high electrical conductivity, with a resistivity of approximately 20-50 μΩ·cm (corresponding to an electrical conductivity of approximately 2×10⁵ to 5×10⁵ S/m), making it suitable for phase-change memory applications. The top electrode material, copper, provides a high thermal conductivity of approximately 400 W/m·K, ensuring efficient heat dissipation from the memory cell, and has an exceptionally high electrical conductivity of approximately 5.8×10⁷ S/m, allowing for efficient current flow through the PCM device of the present disclosure to be formed. The combination of TiN as a thermal protection layer with Cu as a top electrode balances heat retention within the phase-change material while allowing heat removal at the electrode interface.

In another embodiment, the thermal protection material of the thermal protection material layer 55L comprises, and/or consists essentially of, tantalum nitride (TaN), and the top electrode material of the top electrode material layer 56L comprises, and/or consists essentially of, gold (Au). Tantalum nitride possesses a thermal conductivity ranging from 10 W/m·K to 40 W/m·K, making it an effective barrier against heat dissipation while maintaining sufficient electrical conductivity. The electrical conductivity of TaN varies depending on composition but typically ranges from 1×10⁵ to 2×10⁵ S/m. Gold exhibits a thermal conductivity of approximately 318 W/m·K, which is considerably higher than that of TaN, and has a high electrical conductivity of approximately 4.5×10⁷ S/m. As the top electrode material, gold may facilitates efficient heat dissipation from a phase-change memory cell, provides high electrical conductivity and corrosion resistance, and thus, provides enhanced reliability and durability for the phase-change memory device.

In yet another embodiment, the thermal protection material of the thermal protection material layer 55L comprises, and/or consists essentially of, tungsten nitride (WN), and the top electrode material of the top electrode material layer 56L comprises, and/or consists essentially of, silver (Ag). Tungsten nitride has a thermal conductivity ranging from approximately 30 W/m·K to 60 W/m·K, making it suitable for applications requiring controlled thermal dissipation, and an electrical conductivity typically in the range of 1×10⁵ to 3×10⁵ S/m, ensuring sufficient current transport. The top electrode material, silver, provides an exceptionally high thermal conductivity of approximately 429 W/m·K, which aids in heat dissipation from the memory cell, thereby improving thermal management, and an electrical conductivity of approximately 6.3×10⁷ S/m, making it one of the most conductive metals available. The use of WN in conjunction with Ag results in a structure that limits excessive heat loss at the phase-change interface while ensuring rapid cooling through the top electrode.

In another embodiment, the thermal protection material of the thermal protection material layer 55L comprises, and/or consists essentially of, carbon-doped aluminum nitride (C-AlN), and the top electrode material of the top electrode material layer 56L comprises, and/or consists essentially of, aluminum (Al). Carbon-doped aluminum nitride provides a thermal conductivity ranging from approximately 20 W/m·K to 50 W/m·K, depending on the level of doping, thereby allowing for effective heat retention within the phase-change material. The electrical conductivity of carbon-doped aluminum nitride is tunable but generally falls within the range of 10⁴ S/m to 10⁵ S/m, depending on doping concentration and processing conditions. The top electrode material, aluminum, has a thermal conductivity of approximately 237 W/m·K, signifimaytly higher than that of the thermal protection layer, facilitating efficient heat dissipation, and an electrical conductivity of approximately 3.8×10⁷ S/m, ensuring low-resistance current flow. The use of C-AlN for the thermal protection layer, combined with Al for the top electrode, enables a thermal profile optimized for phase-change memory operations.

In one embodiment, the thermal protection material of the thermal protection material layer 55L comprises, and/or consists essentially of, carbide-doped tungsten nitride (C-WN), and the top electrode material of the top electrode material layer 56L comprises, and/or consists essentially of, platinum (Pt). The carbide doping of tungsten nitride reduces its thermal conductivity to approximately 15 W/m·K to 45 W/m·K, while maintaining high electrical conductivity. The reduction of the thermal conductivity prevents premature heat dissipation into the top electrode, and allows lateral spread of the heat toward the sidewalls of each phase-change material portion during operation of phase-change memory cells. The electrical conductivity of carbide-doped tungsten nitride typically ranges from 1×10⁵ S/m to 5×10⁵ S/m, making it a suitable material for electrical and thermal management in phase-change memory. The top electrode material, platinum, exhibits a thermal conductivity of approximately 71 W/m·K, which is sufficiently high to allow for controlled thermal dissipation while ensuring stable electrical performance, and an electrical conductivity of approximately 9.4×10⁶ S/m, providing a reliable electrical contact. The pairing of C-WN with Pt ensures that the phase-change memory cell retains heat within the active region while preventing excessive leakage current.

In an alternative embodiment, the thermal protection material of the thermal protection material layer 55L comprises, and/or consists essentially of, a nitride-based metal (Metal-N), wherein the metal is selected from titanium (Ti), tantalum (Ta), tungsten (W), or aluminum (Al), and wherein the nitride material is further doped with an element selected from carbon (C), aluminum (Al), or boron (B). The top electrode material of the top electrode material layer 56L comprises, and/or consists essentially of, silver (Ag) or copper (Cu). The metal-nitride (Metal-N) composition with B-doping results in thermal conductivities ranging from 10 W/m·K to 50 W/m·K, depending on the doping concentration, providing an effective thermal barrier while ensuring adequate electrical conductivity. The electrical conductivity of B-doped Metal-N materials varies widely but generally falls within the range of 1×10⁵ to 6×10⁵ S/m, depending on the composition and processing parameters. The top electrode materials, silver and copper, exhibit thermal conductivities of 429 W/m·K and 400 W/m·K, respectively, ensuring efficient heat dissipation from the phase-change memory structure, and have electrical conductivities of approximately 6.3×10⁷ S/m (Ag) and 5.8×10⁷ S/m (Cu), thereby providing efficient current conduction. The use of B-doped Metal-N as a thermal protection layer in combination with highly conductive top electrodes such as Ag or Cu provides an optimized thermal profile that enhances phase-change memory performance while minimizing leakage current.

In one embodiment, the thermal protection layer 55L comprises a layer stack containing a first component thermal protection layer including a stoichiometric metal nitride material (such as TiN, TaN, WN, or MoN) in which the atomic ratio of a metal to nitrogen is 1:1, and one or more second component thermal protection layers each comprising a doped metallic material containing a combination of a metallic material and at least one dopant species. In one embodiment, each second component thermal protection layer may comprise a respective metallic material that is derived from TiN, TaN, WN, AlN, C-WN, C-AlN, Cu, Al, Au, Ag, Pt, and W by doping the metallic material with at least one dopant species may be selected from boron (B), carbon (C), aluminum (Al), silicon (Si), germanium (Ge), nitrogen (N), and/or oxygen (O). In this case, the atomic percentage of the implanted dopant species may be in a range from 1 % to 20 %, although lesser or greater atomic percentages may also be employed. The first component thermal protection layer including the stoichiometric metal nitride material (such as TiN, TaN, WN, or MoN) may be deposited directly on the phase-change material layer 54L to prevent diffusion of the dopant species into the phase-change material layer, and the one or more second component thermal protection layers including a respective doped metallic material may be formed thereupon. In one embodiment, the one or more second component thermal protection layers may comprise a layer stack of a first doped metallic material layer including a metal selected from Cu, Al, Au, Ag, Pt, and W and at least one dopant that is selected from boron (B), carbon (C), aluminum (Al), silicon (Si), germanium (Ge), nitrogen (N), and/or oxygen (O), and formed directly on the first component thermal protection layer in order to facilitate lateral spreading of electrical current while functioning as a weak thermal barrier, and further including a second doped metallic material layer including a metallic material selected from TiN, TaN, WN, AlN, C-WN, C-AlN and boron (B), carbon (C), aluminum (Al), silicon (Si), germanium (Ge), nitrogen (N), and/or oxygen (O), and formed on the first doped metallic material layer in order to provide a strong thermal barrier layer.

The top electrode material layer 56L comprises, and/or consists essentially of, a material having a higher thermal conductivity than the thermal protection material. The top electrode material layer 56L has a second thermal conductivity, which is higher than the first thermal conductivity of the thermal protection material layer 55L. The second thermal conductivity may be in a range from 100 W/m·K to 430 W/m·K.

In one embodiment, the top electrode material layer 56L comprises, and/or consists essentially of, a material selected from copper (Cu), silver (Ag), gold (Au), aluminum (Al), platinum (Pt), tungsten (W), tantalum (Ta), titanium (Ti), or metal-like conductive compounds. The conductive compounds may include a metal nitride material that is selected from nitrides of tungsten (W), tantalum (Ta), or titanium (Ti), such as tungsten nitride (WN), tantalum nitride (TaN), or titanium nitride (TiN). The thickness of the top electrode material layer 56L may range from 5 nm to 500 nm. The selected thickness may vary based on electrical or structural performance requirements. The top electrode material layer 56L may be deposited using physical vapor deposition (PVD), electroplating, or atomic layer deposition (ALD). Alternative deposition methods may be used if they achieve a highly conductive top electrode. The combination of the thermal protection material layer 55L and the top electrode material layer 56L may enhance the thermal and electrical performance of the phase-change memory device. The top electrode material layer 56L may facilitate efficient current conduction and stable switching behavior.

The thermal protection material layer 55L restricts heat dissipation from the phase-change material to the top electrode material layer 56L, and thus, causes the heat within the phase-change material to spread along the lateral direction. Thus, the temperature distribution within the phase-change material becomes more uniform during programming. In embodiments in which a phase-change memory cell is programmed into a high resistance state, the amorphous portion of the phase-change material within the phase-change memory cell may have a more uniform thickness distribution due to the presence of the thermal protection material in the phase-change memory cells of the present disclosure.

The thermal protection material layer 55L and the top electrode material layer 56L exhibit distinct thermal properties that contribute to the enhanced performance of the phase-change memory device of the present disclosure. The thermal protection material of the thermal protection material layer 55L has the first thermal conductivity, which is lower than the second thermal conductivity of the top electrode material. The difference in thermal conductivities enhances heat retention and enhanced lateral heat spreading within the phase-change material while providing efficient heat dissipation at an interface with a top electrode. By reducing heat loss through the top electrode material, the thermal protection material facilitates improved energy efficiency and reduced programming current requirements.

In one embodiment, the thermal protection material comprises a metallic nitride material that is doped to reduce its thermal conductivity while maintaining adequate electrical conductivity. The doping of the thermal protection material layer 55L introduces phonon scattering centers that lower its thermal conductivity relative to an undoped metallic nitride of the same composition. In contrast, the top electrode material layer 56L comprises a high-conductivity metal or metal compound selected to maximize heat dissipation away from the memory cell, thus stabilizing the thermal environment of the phase-change material during operation. In one embodiment, the top electrode material layer 56L may consist essentially of a single metallic element.

Additionally, the thermal protection material layer 55L may be positioned directly over the phase-change material layer, forming a thermal interface that regulates the flow of heat. In one embodiment, the thermal protection material layer 55L restricts vertical heat dissipation and causes the generated heat to spread laterally within the phase-change material layer, resulting in a more uniform temperature distribution. This lateral heat spreading effect leads to a more consistent amorphous region thickness when the phase-change material is programmed into a high resistance state, thereby improving the reliability of resistance-based data storage.

The top electrode material layer 56L may be configured to facilitate rapid cooling of the phase-change material following a programming pulse. The thermal conductivity of the top electrode material layer 56L ensures that excess heat may be dissipated efficiently, allowing the phase-change material to return to its stable phase. In contrast, the thermal protection material layer 55L acts as a thermal barrier that mitigates excessive heat loss into the electrode structure. The balance between the impedance to vertical heat flow provided by the thermal protection material layer 55L and the efficient vertical heat flow provided by the top electrode material layer 56L allows for sufficient retention of heat within a phase-change material portion during programming, while allows sufficient heat flow through a top electrode to prevent overheating of the phase-change material portion.

In another embodiment, the electrical conductivity of the thermal protection material layer 55L may be higher than that of an undoped metallic nitride, ensuring adequate current conduction while still serving as a thermal insulator. The top electrode material layer 56L, having a high electrical conductivity, ensures minimal voltage drop across the memory cell, further optimizing power efficiency. The combination of the material properties of the thermal protection material layer 55L and the top electrode material layer 56L allows for a robust phase-change memory device architecture that supports rapid switching and extended endurance. Use of differential thermal conductivities between the thermal protection material layer 55L and the top electrode material layer 56L, the phase-change memory device of the present disclosure provides a balance between efficient thermal management and reliable data retention.

The hardmask material layer 58L comprises a dielectric hardmask material such as silicon nitride, silicon carbonitride, silicon oxide, a dielectric metal oxide, or a combination thereof. The thickness of the hardmask material layer 58L may be in a range from 5 nm to 100 nm, although lesser or greater thicknesses may also be used.

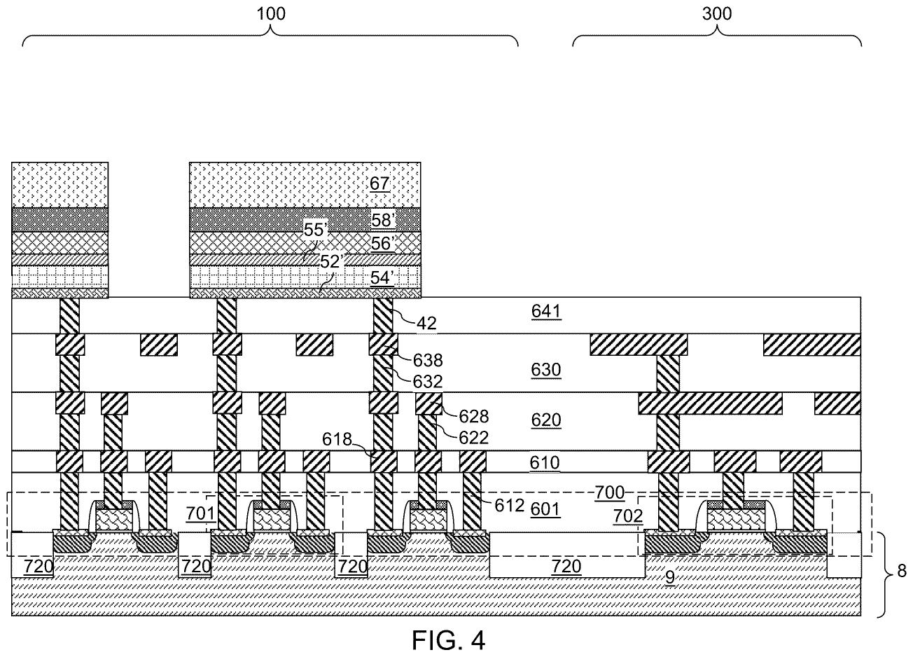

Referring to FIG. 4, the hardmask material layer 58L, the top electrode material layer 56L, and the phase-change material layer 54L may be patterned into plate stacks (58, 56, 55, 54, 52). Specifically, a first patterned etch mask layer 67 may be formed over the continuous layer stack (52L, 54L, 55L, 56L, 58L). For example, the first patterned etch mask layer 67 may be formed by applying a photoresist layer over the continuous layer stack (52L, 54L, 55L, 56L, 58L), and lithographically patterning the photoresist layer into an array of discrete patterned photoresist material portions. In one embodiment, the first patterned etch mask layer 67 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape. The lateral dimensions, such as the length and the width, of each patterned photoresist material portion may be in a range from 40 nm to 1,000 nm, although lesser or greater lateral dimensions may also be used. In one embodiment, the lateral dimensions of each patterned photoresist material portion may be selected such that the area of a patterned photoresist material portion corresponds to the area of a single phase-change memory material portion for a phase-change memory cell.

An anisotropic etch process may be performed to etch portions of the hardmask material layer 58L, the top electrode material layer 56L, the thermal protection material layer 55L, the phase-change material layer 54L, and the bottom electrode material layer 52L that are not masked by the first patterned etch mask layer 67. The anisotropic etch process may use a sequence of etch chemistries that sequentially etches the materials of the hardmask material layer 58L, the top electrode material layer 56L, the thermal protection material layer 55L, the phase-change material layer 54L, and the bottom electrode material layer 52L.

For example, the anisotropic etch process may comprise a first anisotropic etch step that etches unmasked portions of the hardmask material layer 58L, a second anisotropic etch step that etches unmasked portions of the top electrode material layer 56L, a third anisotropic etch step that etches unmasked portions of the thermal protection material layer 55L, a fourth anisotropic etch process that etches the phase-change material layer 54L, and a fifth anisotropic etch process that etches the bottom electrode material layer. The etch chemistry for the first anisotropic etch step may include fluorine-based gases such as CF₄, CHF₃, and/or SF₆, which are effective in etching dielectric materials like silicon nitride, silicon carbonitride, silicon oxide, or dielectric metal oxides. The top electrode material layer 56L may comprise a metallic material such as W, Ta, Ti, Mo, WN, TiN, and/or MoN, the etch chemistry of the second anisotropic etch step may include chlorine-based gases such as Cl₂ or BCl₃, and may optionally include Ar or N₂.

The third anisotropic etch process selectively etches unmasked portions of the thermal protection material layer 55L while preserving the underlying phase-change material layer 54L. The thermal protection material layer 55L comprises a metal nitride material, which may include titanium nitride (TiN), tantalum nitride (TaN), tungsten nitride (WN), aluminum nitride (AlN), or doped variants such as carbon-doped tungsten nitride (C-WN) and boron-doped titanium nitride (B-TiN). The etch chemistry for this step may include chlorine-based and fluorine-based gases such as BCl₃, Cl₂, CF₄, or SF₆, which are effective in etching metal nitride materials. The process conditions are carefully controlled to maintain high etch selectivity to the phase-change material while ensuring minimal damage to adjacent structures. Additionally, the etch process may involve a low-pressure, high-ion-energy environment to enhance anisotropy and profile control.

The fourth anisotropic etch process etches unmasked portions of the phase-change material layer 54L, which consists of a chalcogenide-based phase-change material capable of switching between crystalline and amorphous states. The phase-change material may include germanium-antimony-telluride (GST) compounds, such as Ge₂Sb₂Te₅, GeSb₂Te₄, or doped GST materials (e.g., N-doped, Si-doped, C-doped, Ge-doped, Ru-doped, or Al-doped GST). The etch chemistry for this step may include halogen-based gases such as Cl₂, HBr, or BCl₃, optionally combined with O₂ or Ar to optimize etch selectivity and prevent oxidation. This step is precisely controlled to avoid sidewall damage to the phase-change material, ensuring reliable resistive switching behavior in the final device. Since halogen-based etching may cause sidewall roughness, an in-situ surface treatment may be applied to smooth the phase-change material edges and minimize variability in electrical resistance.

The fifth anisotropic etch process etches unmasked portions of the bottom electrode material layer 52L, which comprises a high-conductivity metallic material. The bottom electrode material layer 52L may include titanium nitride (TiN), tantalum nitride (TaN), tungsten nitride (WN), molybdenum nitride (MoN), ruthenium (Ru), or tungsten (W). The etch chemistry for this step may involve chlorine-based gases such as Cl₂, BCl₃, or HBr, and may optionally include Ar or N₂ to enhance anisotropy and profile control. Use of a controlled etch chemistry ensures that the bottom electrode retains its structural integrity while providing a stable electrical connection to the underlying interconnect structure. The fifth anisotropic etch process may be optimized to prevent excessive sidewall tapering, ensuring reliable current conduction in the phase-change memory cells to be subsequently formed.

Each patterned portion of the hardmask material layer 58L comprises an in-process hardmask plate 58′. Each patterned portion of the top electrode material layer 56L comprises an in-process top electrode 56′. Each patterned portion of the thermal protection material layer 55L comprises an in-process thermal protection plate 55′. Each patterned portion of the phase-change material layer 54L comprises an in-process phase-change material portion 54′. Each patterned portion of the bottom electrode material layer 52L comprises an in-process plate bottom electrode 52′. Thus, the combination of the hardmask material layer 58L, the top electrode material layer 56L, the thermal protection material layer 55L, the phase-change material layer 54L, and the bottom electrode material layer 52L is patterned into in-process plate stacks (58′, 56′, 55′, 54′, 52′) each including an in-process plate bottom electrode 52′, an in-process phase-change material portion 54′, an in-process thermal protection plate 55′, an in-process top electrode 56′, and an in-process hardmask plate 58′. Within each in-process plate stack (58′, 56′, 55′, 54′, 52′), the sidewalls of the in-process plate bottom electrode 52′, the in-process phase-change material portion 54′, the in-process thermal protection plate 55′, the in-process top electrode 56′, and the in-process hardmask plate 58′ are vertically coincident to one another.

In summary, in-process plate stacks (58′, 56′, 55′, 54′, 52′) containing respective patterned portions of the hardmask material layer 58L, the top electrode material layer 56L, the thermal protection material layer 55L, the phase-change material layer 54L, and the bottom electrode material layer 52L may be formed by patterning the stacked layers in sequence using an anisotropic etch process. The patterning process sequentially removes unmasked portions of the material layers while maintaining etch selectivity between different materials. The hardmask material layer 58L, the top electrode material layer 56L, the thermal protection material layer 55L, the phase-change material layer 54L, and the bottom electrode material layer 52L are etched into in-process plate stacks (58′, 56′, 55′, 54′, 52′), where each stack comprises an in-process hardmask plate 58′, an in-process top electrode 56′, an in-process thermal protection plate 55′, an in-process phase-change material portion 54′, and an in-process bottom electrode 52′. Within each in-process plate stack (58′, 56′, 55′, 54′, 52′), the sidewalls of all patterned layers are vertically coincident, ensuring precise alignment and structural integrity of the phase-change memory structure. After patterning, the first patterned etch mask layer 67 may be subsequently removed, for example, by ashing or dissolution in a solvent.

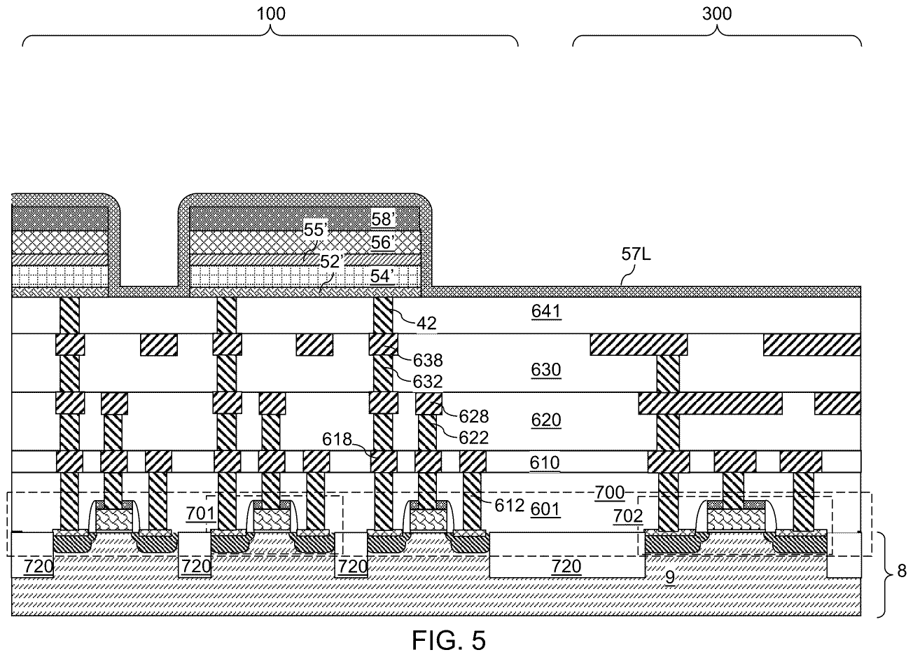

Referring to FIG. 5, a spacer material layer 57L may be deposited on the physically exposed surfaces of the in-process plate stacks (58′, 56′, 55′, 54′, 52′) and on the physically exposed segments of the top surface of a dielectric material layer (such as the lower fourth interconnect-level dielectric material layer 641). The spacer material layer 57L comprises a material having a lower electrical conductivity than the material of the bottom electrode material layer 52L. In one embodiment, the spacer material layer 57L comprises a material having an electrical conductivity that is less than 1/100 of the electrical conductivity of the material of the bottom electrode material layer 52L. In one embodiment, the spacer material layer 57L comprises a material having a second electrical conductivity in a range from 1.0×10⁻¹⁵ S/m to 1.0×10³ S/m. In one embodiment, the spacer material layer 57L comprises an insulator material having an electrical conductivity less than 1.0×10⁻⁵ S/m. In another embodiment, the spacer material layer 57L comprises a semiconducting material having an electrical conductivity in a range from 1.0×10⁻⁵ S/m to 1.0×10⁵ S/m. The thickness of the spacer material layer 57L may be in a range from 1 nm to 20 nm, such as from 2 nm to 4 nm, although lesser or greater thicknesses may also be used.

The spacer material layer 57L may be deposited directly on all sidewalls of the various layers that comprise the in-process plate stacks (58′, 56′, 55′, 54′, 52′) and a top surface of the dielectric material layer (such as the lower fourth interconnect-level dielectric material layer 641) after patterning the hardmask material layer 58L, the top electrode material layer 56L, the thermal protection material layer 55L, the phase-change material layer 54L, and the bottom electrode material layer 52L into the in-process plate stacks (58′, 56′, 55′, 54′, 52′). In other words, all sidewalls of the plate stacks in-process plate stacks (58′, 56′, 55′, 54′, 52′) are contacted by the spacer material layer 57L upon deposition of the spacer material layer 57L. Thus, vertically-extending portions of the spacer material layer 57L contact all sidewalls of a respective one of the in-process plate stacks (58′, 56′, 55′, 54′, 52′).

In one embodiment, the spacer material layer 57L may comprise a metallic nitride material layer that is deposited by a conformal deposition process such as a chemical vapor deposition process. In one embodiment, the spacer material layer 57L may comprise a second metallic nitride material, which may comprise, and/or may consist essentially of, TiN, TaN, WN, and/or MoN. In this embodiment, the electrical conductivity of the second metallic nitride material may be reduced by incorporating carbon atoms or nitrogen atoms into the metallic nitride material layer by in-situ doping or ex-situ doping of carbon atoms or nitrogen atoms, i.e., incorporation of the carbon atoms or the nitrogen atoms during deposition of the spacer material layer 57L or after deposition of the spacer material layer 57L. For example, the carbon atoms or the nitrogen atoms may be provided by a reactive carbon-containing gas (such as acetylene or ethylene) or a reactive nitrogen-containing gas (such as ammonia) during a chemical vapor deposition that deposits the spacer material layer 57L. Alternatively, the spacer material layer 57L may be exposed to an ambient containing reactive carbon-containing species or reactive nitrogen-containing species at an elevated temperature after the deposition process that deposits the spacer material layer 57L. Yet alternatively, an ion implantation process or a plasma doping process may be performed after the deposition process that deposits the spacer material layer 57L.

The carbon atoms or the nitrogen atoms are incorporated into the second metallic nitride material of the spacer material layer 57L at an atomic concentration such that the electrical conductivity of the doped metallic nitride material of the spacer material layer 57L after incorporation of the carbon atoms or the nitrogen atoms is less than ⅓ of the electrical conductivity of the second metallic nitride material prior to the incorporation of the carbon atoms or the nitrogen atoms. In an illustrative example, the electrical conductivity of the spacer material layer 57L after incorporation of the carbon atoms or the nitrogen atoms may be in a range from 1.0×10¹ S/cm to 1.0×10⁵ S/cm.

Generally, the ratio of the metal atoms to nitrogen atoms in a stoichiometric metallic compound MN, in which M is Ta, Ti, Mo, or W, is 1:1. In embodiments in which nitrogen doping is used, upon doping of a stoichiometric metallic compound with nitrogen atoms to form the spacer material layer 57L of the present disclosure, the ratio of the metal atoms to nitrogen atoms in the spacer material layer 57L may be in a range from 1:1.02 to 1:1.05. In embodiments in which carbon doping is used, upon doping of a stoichiometric metallic compound with carbon atoms to form the spacer material layer 57L of the present disclosure, the ratio of the metal atoms to nitrogen atoms to carbon atoms in the spacer material layer 57L may be in a range from 1:1:0.02 to 1:1:0.05. Generally, the atomic concentration of the extra nitrogen atoms in a nitrogen-doped metallic nitride material may be in a range from 0.02 times the atomic concentration of the metal atoms to 0.05 times the atomic concentration of the metal atoms. Likewise, the atomic concentration of the carbon atoms in a carbon-doped metallic nitride material may be in a range from 0.02 times the atomic concentration of the metal atoms to 0.05 times the atomic concentration of the metal atoms.

In one embodiment, the second metallic nitride material of the spacer material layer 57L after the doping process may have an electrical conductivity that is less than 1/100 of the electrical conductivity of the first metallic nitride material of the plate bottom electrodes 52. In one embodiment, the first metallic nitride material of the bottom electrode material layer 52L and the second metallic nitride material (which is a doped metallic nitride material) of the spacer material layer 57L are selected such that the resistance of a plate bottom electrode 52 and the resistance of a sidewall spacer to be patterned from the spacer material layer 57L dominate the resistance of a phase memory material cell in a high resistance state. In this embodiment, the resistance of the amorphous volume of a phase-change material portion does not determine the resistance of high resistance states of a phase-change memory cell. Thus, the phase-change memory cell may operate without significant degradation caused by any resistance drift of a phase-change material.

Alternatively, the spacer material layer 57L may consist of at least one insulating material such as silicon oxide, silicon nitride, and/or a dielectric metal oxide. In this embodiment, the resistance of a plate bottom electrode 52 and the resistance of a phase-change material portion 54 in an amorphous phase may dominate the resistance of states of phase memory material cells in a high resistance state.

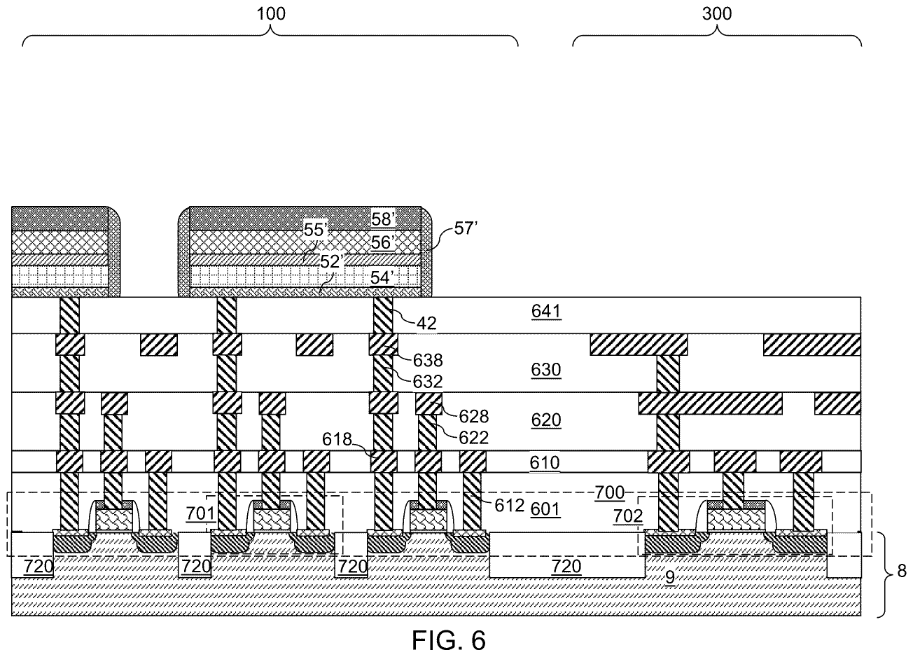

Referring to FIG. 6, an anisotropic etch process may be performed to remove horizontally-extending portions of the spacer material layer 57L. The anisotropic etch process is also referred to as a spacer etch process. The anisotropic etch process removes horizontally-extending portions of the spacer material layer 57L. Each remaining vertically-extending portion of the spacer material layer 57L constitutes an in-process sidewall spacer 57′ that laterally surrounds a respective in-process plate stack (58′, 56′, 55′, 54′, 52′). Generally, an in-process sidewall spacer 57 may be formed around each in-process plate stack (58′, 56′, 55′, 54′, 52′) by conformally depositing and anisotropically etching a layer of the sidewall spacer material.

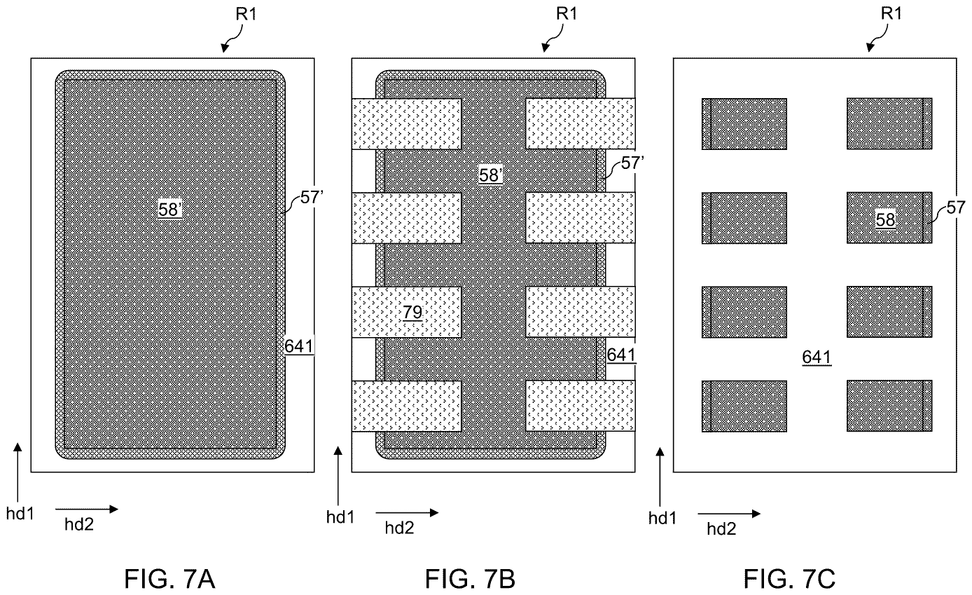

FIG. 7A-7C are sequential top-down views of a region of the first embodiment structure during patterning of the in-process plate stacks (58′, 56′, 55′, 54′, 52′) into plate stacks (58, 56, 55, 54, 52) of a hardmask plate 58, a top electrode 56, a thermal protection plate 55, a phase-change material portion 54, and a plate bottom electrodes 52.

Referring to FIG. 7A, a region of the first embodiment structure including a plate stack (58′, 56′, 55′, 54′, 52′) and an in-process sidewall spacer 57′ is illustrated at the processing step of FIG. 6. The in-process plate stack (58′, 56′, 55′, 54′, 52′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 7B, the region of the first embodiment structure is illustrated after formation of a second patterned etch mask layer 79, which may be a patterned photoresist layer. The second etch mask layer 79 has a pattern that is different from the pattern of the first patterned etch mask layer 67 used at the processing steps of FIG. 4. The illustrated portion of the second patterned etch mask layer 79 may comprise a two-dimensional array, such as a 2×N array, of patterned discrete etch mask material portions (such as patterned photoresist material portions) that cover 2N segments of the first sidewalls of the in-process plate stack (58′, 56′, 55′, 54′, 52′). In the illustrated example, the integer N is 4. Generally, the integer N may be any positive integer. As discussed above, the in-process plate stack (58′, 56′, 55′, 54′, 52′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 7C, an anisotropic etch process may be performed to etch unmasked portions of the in-process hardmask plates 58′, the in-process top electrodes 56′, the in-process thermal protection plates 55′, the in-process phase-change material portions 54′, the in-process plate bottom electrodes 52′, and the in-process sidewall spacers 57′. The anisotropic etch process etches unmasked regions of the combination of the in-process plate stacks (58′, 56′, 55′, 54′, 52′) and the in-process sidewall spacers 57′ (which are remaining portion of the spacer material layer 57L after the processing steps of FIG. 6) that are not covered by the second patterned etch mask layer 79 (which may be a patterned photoresist layer). Each contiguous set of patterned portions of an in-process plate stack (58′, 56′, 55′, 54′, 52′) comprises a plate stack (58, 56, 55, 54, 52) including a respective hardmask plate 58, a respective top electrode 56, a respective thermal protection plate 55, a respective phase-change material portion 54, and a respective plate bottom electrode 52. The lateral dimensions of each plate stack (58, 56, 55, 54, 52) may be in a range from 20 nm to 100 nm, although lesser or greater lateral dimensions may also be used.

Generally, an in-process plate stack (58′, 56′, 55′, 54′, 52′) may be patterned into at least one row of plate stacks (58, 56, 55, 54, 52) arranged along a first horizontal direction hd1 or along a second horizontal direction hd2. In one embodiment, each in-process plate stack (58′, 56′, 55′, 54′, 52′) may be divided into an M×N array of plate stacks (58, 56, 55, 54, 52). In one embodiment, the first embodiment structure may comprise a P×Q array of in-process plate stacks (58′, 56′, 55′, 54′, 52′) after the processing step of FIG. 6, and each in-process plate stack (58′, 56′, 55′, 54′, 52′) may be subsequently divided into an M×N array of plate stacks (58, 56, 55, 54, 52). In this embodiment, a PM×QN array of plate stacks (58, 56, 55, 54, 52) may be formed by the anisotropic etch process. P and Q may be independent integers greater than 1, and may be independently in a range from 2 to 2¹⁶.

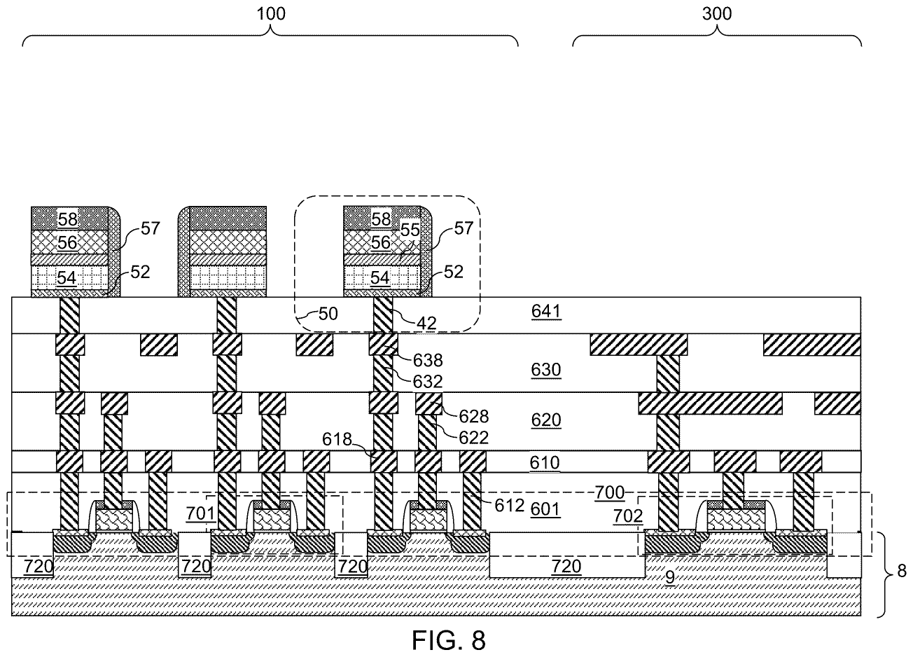

Referring to FIG. 8, the first embodiment structure is illustrated after formation of stacks of a hardmask plate 58, a top electrode 56, a thermal protection plate 55, a phase-change material portion 54, and a plate bottom electrode 52. Each contiguous combination of a via bottom electrode 42, a plate bottom electrode 52, a phase-change material portion 54, a thermal protection plate 55, a top electrode 56, a hardmask plate 58, and a sidewall spacer 57 constitutes a phase-change memory cell 50. A two-dimensional array of phase-change memory cells 50 may be formed in the memory array region 100. Each phase-change memory cell 50 comprises a via bottom electrode 42 located within a dielectric material layer (such as a lower fourth interconnect-level dielectric material layer 641); a stack comprising a plate bottom electrode 52, a phase-change material portion 54, a thermal protection plate 55, and a top electrode 56 and located on the via bottom electrode 42; and a sidewall spacer 57 contacting sidewalls of the top electrode 56 and the phase-change material portion 54 and contacting a peripheral segment of a top surface of the plate bottom electrode 52. For each phase-change memory cell 50, each sidewall of the plate bottom electrode 52 may be vertically coincident with a respective outer sidewall of the sidewall spacer 57.

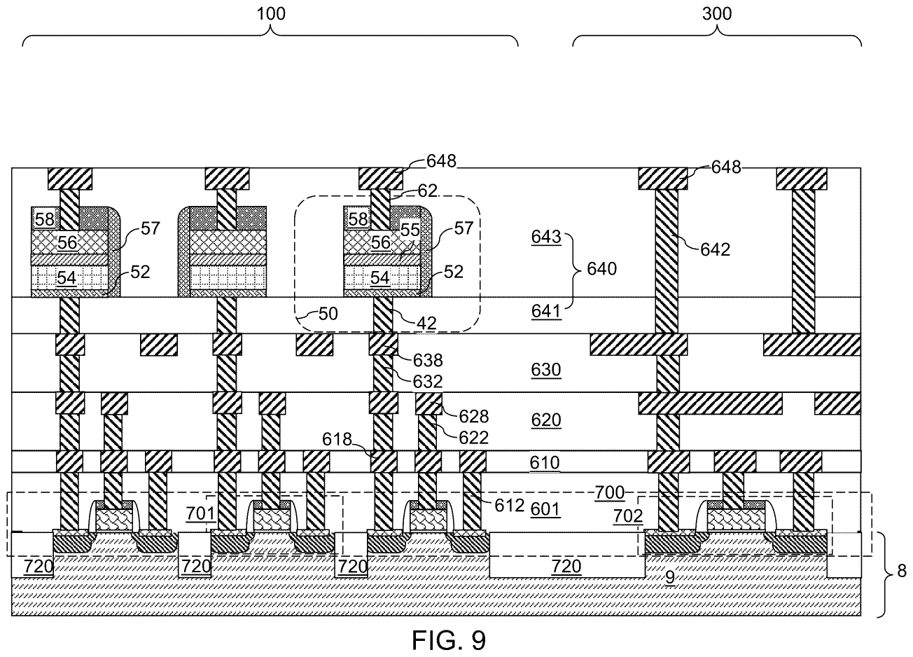

Referring to FIG. 9, an encapsulation dielectric layer 643 and additional metal interconnect structures (62, 642, 648) may be formed over the phase-change memory cells 50. The encapsulation dielectric layer 643 comprises at least one interlayer dielectric material such as silicon oxide, silicon nitride, and/or silicon carbide nitride. The additional metal interconnect structures (62, 642, 648) may comprise top-contact via structures 62 contacting a top surface of a respective one of the top electrodes 56, peripheral via structures 642 that are formed on a respective one of the lower-level metal interconnect structures (612, 618, 622, 628, 632, 638) (such as a respective one of the third metal line structures 638), and fourth metal line structures 648 that are formed on the top-contact via structures 62 and the peripheral via structures 642. Top surfaces of the fourth metal line structures 648 may be coplanar with the horizontal top surface of the encapsulation dielectric layer 643.

The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed to provide electrical connections between the top electrodes 56 of the phase-change memory cells 50 and the various semiconductor devices 700 that underlie the dielectric material layers (601, 610, 620, 630, 640).

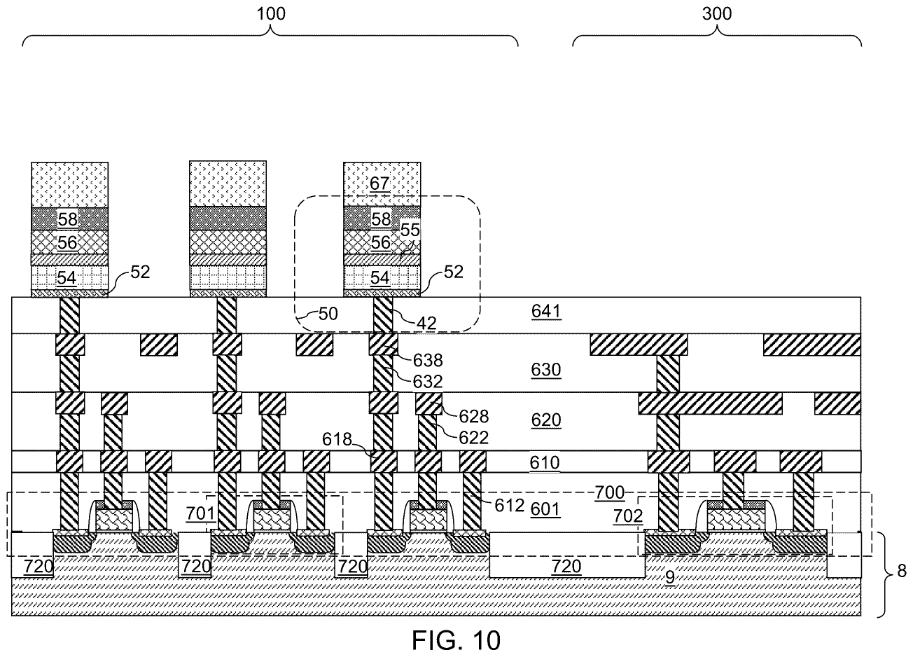

Referring to FIG. 10, a second embodiment structure according to a second embodiment of the present disclosure is illustrated. The second embodiment structure illustrated in FIG. 10 may be derived from the first embodiment structure described with reference to FIG. 3 by changing the pattern of the first patterned etch mask layer 67 such that each patterned portion of the first patterned etch mask layer 67 has the same area as a phase-change material portion 56 of a phase-change memory cell 50.

Each patterned portion of the hardmask material layer 58L comprises a hardmask plate 58. Each patterned portion of the top electrode material layer 56L comprises a top electrode 56. Each patterned portion of the thermal protection material layer 55L comprises a thermal protection plate 55. Each patterned portion of the phase-change material layer 54L comprises a phase-change material portion 54. Each patterned portion of the bottom electrode material layer 52L comprises a plate bottom electrode 52. Thus, the combination of the hardmask material layer 58L, the top electrode material layer 56L, the thermal protection material layer 55L, the phase-change material layer 54L, and the bottom electrode material layer 52L is patterned into plate stacks (58, 56, 55, 54, 52) each including a plate bottom electrode 52, a phase-change material portion 54, a thermal protection plate 55, a top electrode 56, and a hardmask plate 58. Within each plate stack (58, 56, 55, 54, 52), the sidewalls of the plate bottom electrode 52, the phase-change material portion 54, the thermal protection plate 55, the top electrode 56, and the hardmask plate 58 are vertically coincident to one another. The lateral dimensions of each plate stack (58, 56, 55, 54, 52) may be in a range from 20 nm to 100 nm, although lesser or greater lateral dimensions may also be used.

In summary, plate stacks (58, 56, 55, 54, 52) containing respective patterned portions of the hardmask material layer 58L, the top electrode material layer 56L, the thermal protection material layer 55L, the phase-change material layer 54L, and the bottom electrode material layer 52L may be formed by patterning the stacked layers in sequence using an anisotropic etch process. The patterning process sequentially removes unmasked portions of the material layers while maintaining etch selectivity between different materials. The hardmask material layer 58L, the top electrode material layer 56L, the thermal protection material layer 55L, the phase-change material layer 54L, and the bottom electrode material layer 52L are etched into plate stacks (58, 56, 55, 54, 52), where each stack comprises a hardmask plate 58, a top electrode 56, a thermal protection plate 55, a phase-change material portion 54, and a bottom electrode 52. Within each plate stack (58, 56, 55, 54, 52), the sidewalls of all patterned layers are vertically coincident, ensuring precise alignment and structural integrity of the phase-change memory structure.

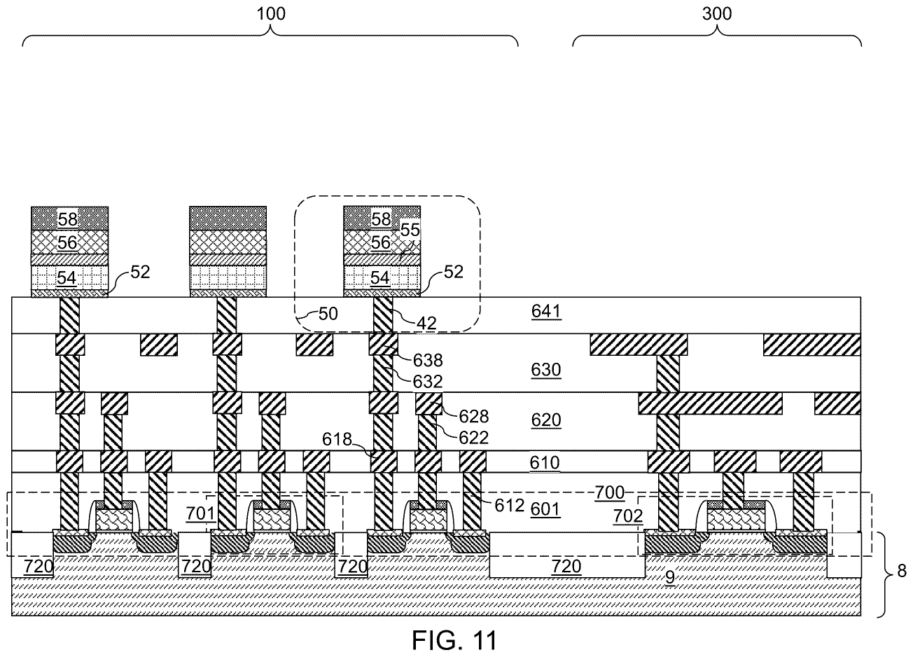

Referring to FIG. 11, the first patterned etch mask layer 67 may be subsequently removed, for example, by ashing or dissolution in a solvent.

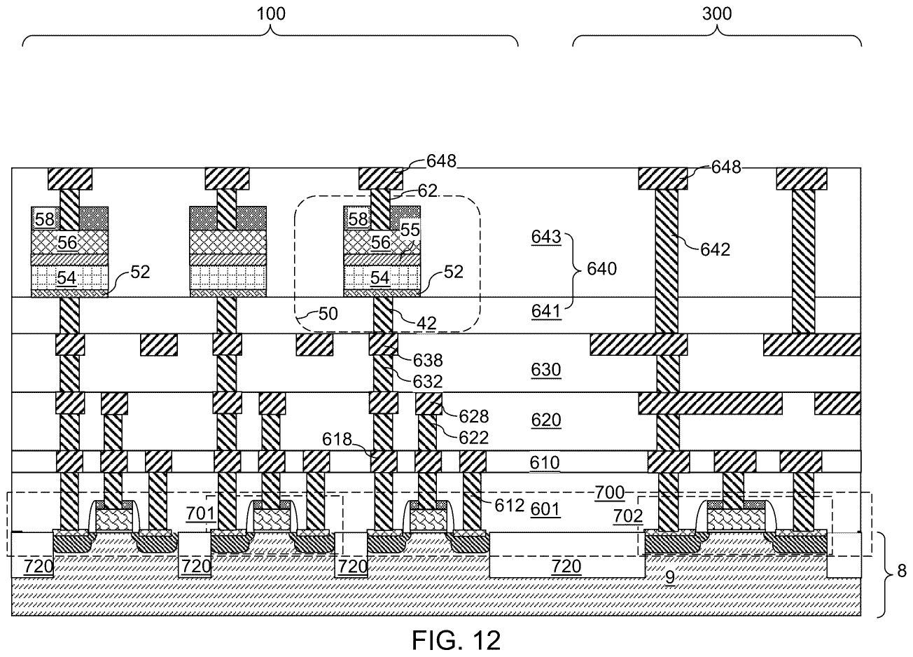

Referring to FIG. 12, the processing steps described with reference to FIG. 9 may be performed to form an encapsulation dielectric layer 643 and additional metal interconnect structures (62, 642, 648).

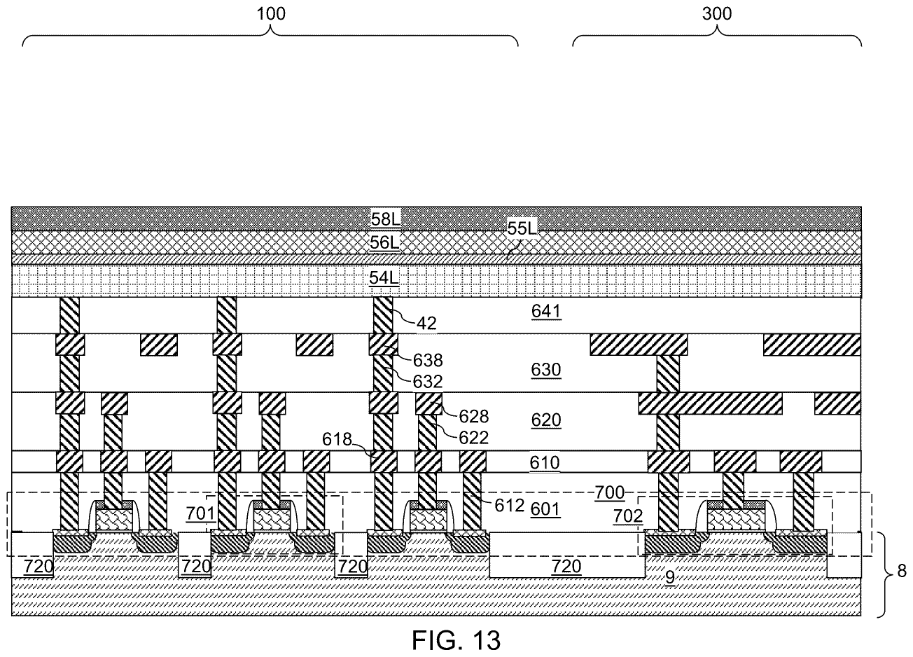

Referring to FIG. 13, a third embodiment structure according to a third embodiment of the present disclosure is illustrated. The third embodiment structure may be derived from the first embodiment structure illustrated in FIG. 3 by omitting formation of a bottom electrode material layer 52L. Thus, the phase-change material layer 54L may be deposited directly on a top surface of a dielectric material layer (such as the lower fourth interconnect-level dielectric material layer 641).

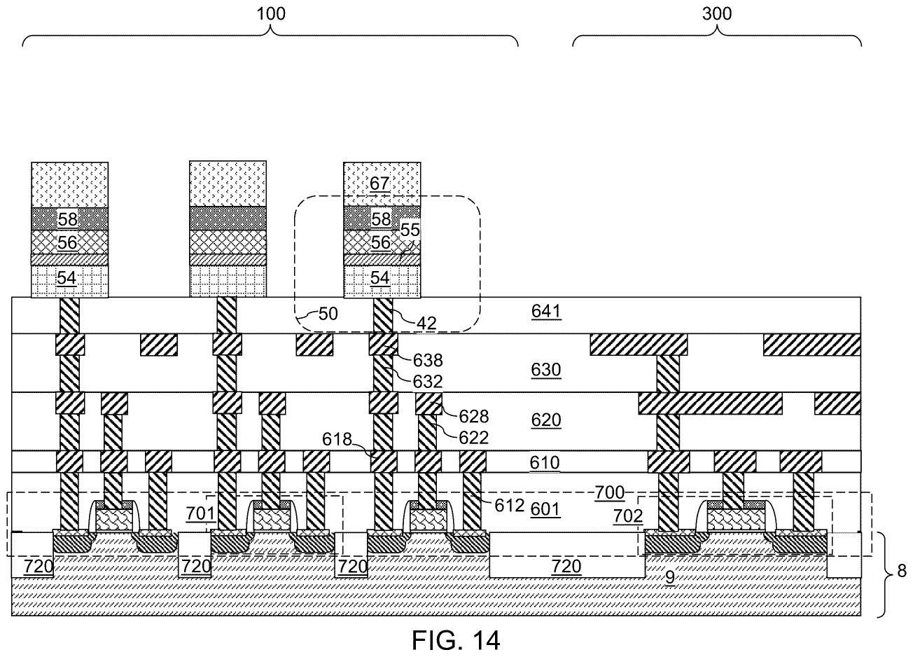

Referring to FIG. 14, the processing steps described with reference to FIG. 10 may be performed with a modification in the anisotropic etch process in view of the absence of the bottom electrode material layer 52L in the third embodiment structure.

The combination of the hardmask material layer 58L, the top electrode material layer 56L, the thermal protection material layer 55L, and the phase-change material layer 54L is patterned into plate stacks (58, 56, 55, 54) each including a phase-change material portion 54, a thermal protection plate 55, a top electrode 56, and a hardmask plate 58. Within each plate stack (58, 56, 55, 54), the sidewalls of the phase-change material portion 54, the thermal protection plate 55, the top electrode 56, and the hardmask plate 58 are vertically coincident to one another. The lateral dimensions of each plate stack (58, 56, 55, 54) may be in a range from 20 nm to 100 nm, although lesser or greater lateral dimensions may also be used.

In summary, plate stacks (58, 56, 55, 54) containing respective patterned portions of the hardmask material layer 58L, the top electrode material layer 56L, the thermal protection material layer 55L, and the phase-change material layer 54L are formed by patterning the stacked layers in sequence using an anisotropic etch process. The patterning process sequentially removes unmasked portions of the material layers while maintaining etch selectivity between different materials. The hardmask material layer 58L, the top electrode material layer 56L, the thermal protection material layer 55L, and the phase-change material layer 54L are etched into plate stacks (58, 56, 55, 54), where each stack comprises a hardmask plate 58, a top electrode 56, a thermal protection plate 55, and a phase-change material portion 54. Within each plate stack (58, 56, 55, 54), the sidewalls of all patterned layers are vertically coincident, ensuring precise alignment and structural integrity of the phase-change memory structure.

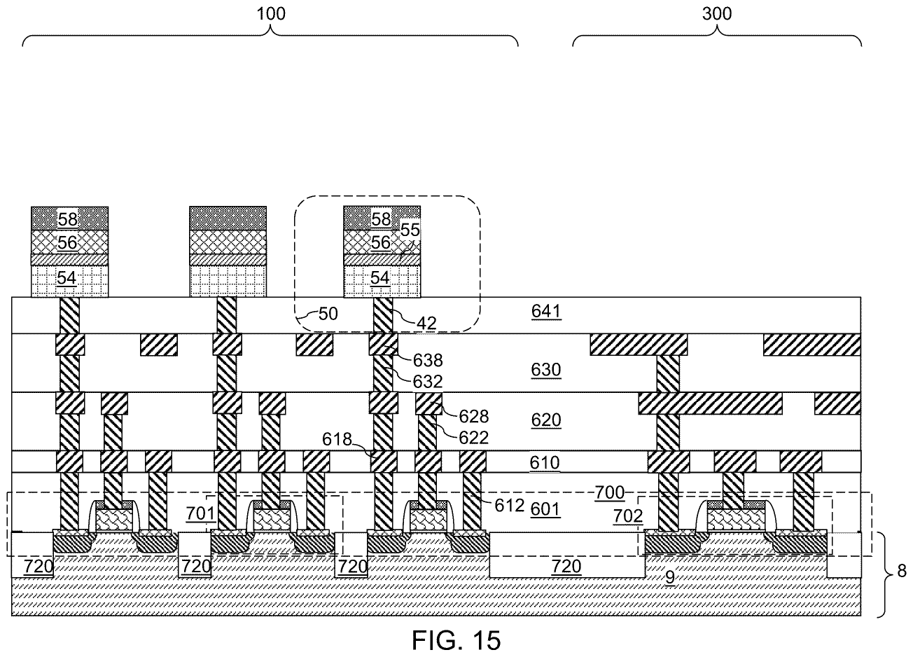

Referring to FIG. 15, the first patterned etch mask layer 67 may be subsequently removed, for example, by ashing or dissolution in a solvent.

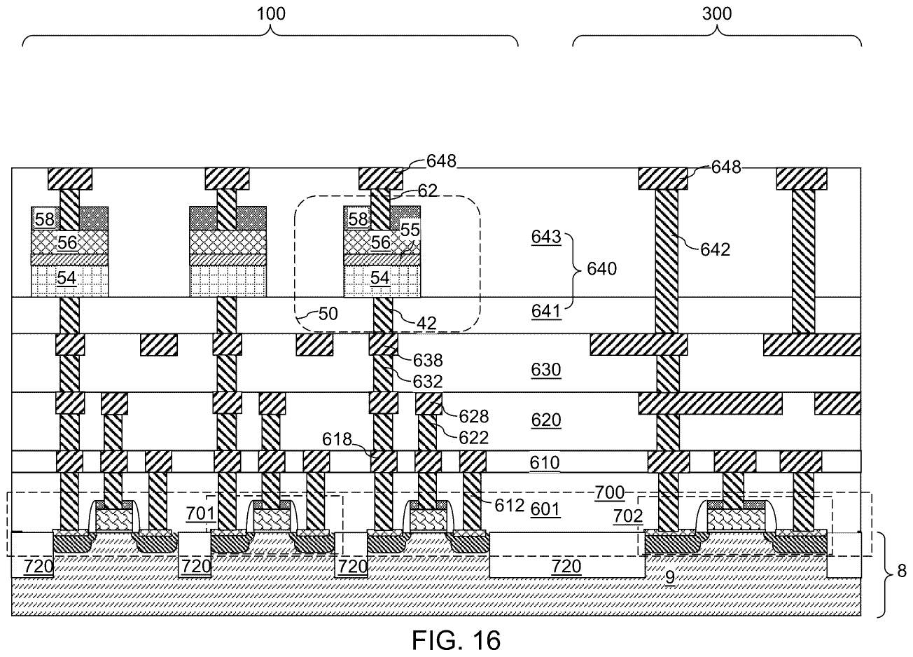

Referring to FIG. 16, the processing steps described with reference to FIG. 9 may be performed to form an encapsulation dielectric layer 643 and additional metal interconnect structures (62, 642, 648).

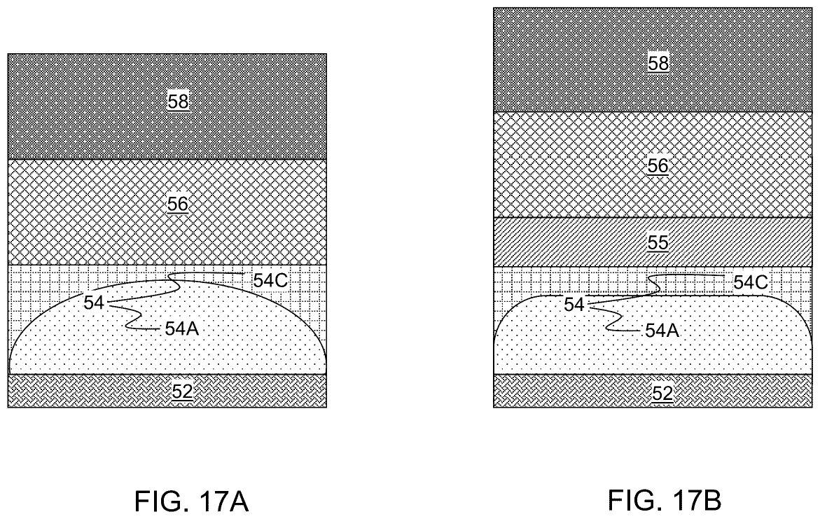

FIG. 17A is a vertical cross-sectional view of a comparative exemplary phase-change memory cell that does not use any thermal protection plate in a high resistance state. FIG. 17B is a vertical cross-sectional view of an exemplary phase-change memory cell according to an embodiment of the present disclosure in a high resistance state.

The phase-change memory cell of the present disclosure illustrated in FIG. 17B includes an amorphous phase-change material region 54A located at the periphery of the phase-change material portion 54 in the high resistance state. The amorphous phase-change material region 54A provides a high-resistance region, while a crystalline phase-change material portion provides a low-resistance region that generates a leakage current for the high-resistance state. The thickness of the amorphous phase-change material region 54A in the phase-change memory cell of the present disclosure is greater than the thickness of an amorphous phase-change material region 54A in a comparative exemplary memory cell illustrated in FIG. 17A. In the phase-change memory cell of the present disclosure, the thermal protection plate 55 in FIG. 17B is positioned between the phase-change material portion 54 and the top electrode 56. The thermal protection plate 55 comprises a thermal protection material having a first thermal conductivity that is lower than the second thermal conductivity of the top electrode material. This configuration may restrict heat dissipation from the phase-change material to the top electrode material layer 56, potentially causing the heat within the phase-change material to spread along the lateral direction.

As a result, the temperature distribution within the phase-change material portion 54 in the embodiment configuration of FIG. 17B becomes more uniform during programming as compared to the phase-change memory cell that does not use any thermal protection plate in a high resistance state illustrated in FIG. 17A. In instances in which a phase-change memory cell is programmed into a high resistance state, the amorphous portion 54A of the phase-change material within the phase-change memory cell of the present disclosure may have a more uniform thickness distribution due to the presence of the thermal protection material in the embodiment phase-change memory cells of the present disclosure.

The embodiment thermal protection plate 55 functions as a thermal barrier that mitigates excessive heat loss into the electrode structure. This may provide an enhanced precision control over phase-change dynamics, potentially leading to improved retention characteristics and lower power consumption. The thermal protection plate 55 increases the retention of the heat in the phase-change material portion 54, and allows for more efficient programming of the phase-change memory cell.

Thus, the various embodiment configurations of the phase-change memory cell of the present disclosure may provide enhanced thermal efficiency. The thermal protection plate enhances heat retention within the phase-change material, and provides more efficient programming operations during which sufficient heat is retained within a phase-change material portion. Further, the various embodiment configurations of the phase-change memory cell of the present disclosure may provide enhanced temperature uniformity within the phase-change material portion 54 during programming. The more uniform temperature distribution may result in a more consistent amorphous region thickness, potentially improving the reliability of resistance-based data storage.

Further, the various embodiment configurations of the phase-change memory cell of the present disclosure may provide lower power consumption. By restricting heat dissipation, the embodiment phase-change memory cell of the present disclosure may be programmed with less energy consumption. In addition, the various embodiment configurations of the phase-change memory cell of the present disclosure may provide enhanced temperature control on the phase-change material portion 54. The embodiment thermal protection plate 55 may allow for more precise control over the phase-change process, potentially leading to improved device performance and reliability. The enhanced lateral heat flow within the phase-change material portion 54 allows the scaling of phase-change memory devices to smaller dimensions while reducing degradation in electrical performance due to leakage currents in the high-resistance state.

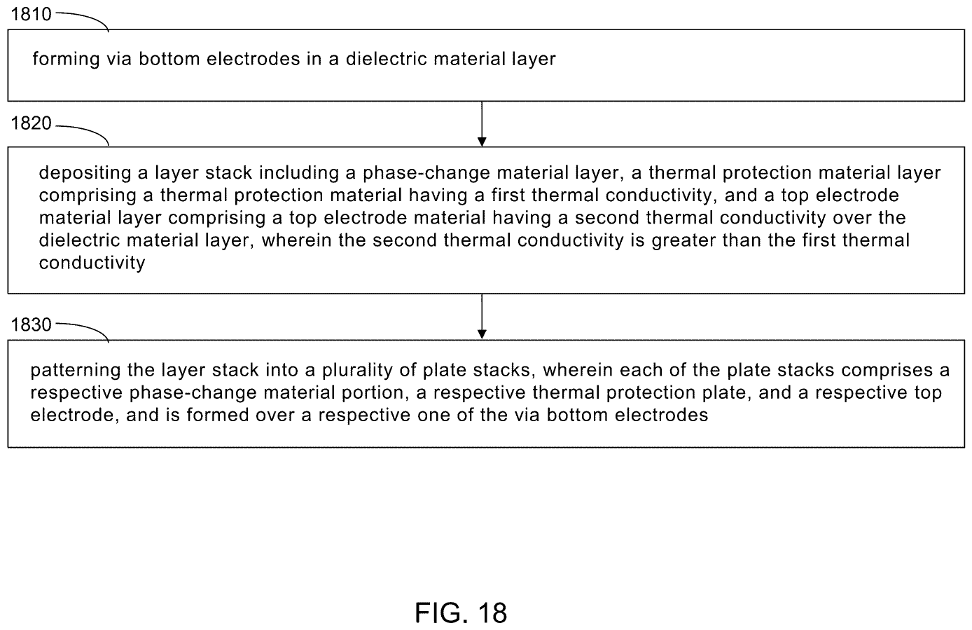

FIG. 18 is a first flowchart that illustrates general processing steps for manufacturing a device structure according to embodiments of the present disclosure.

Referring to step 1810 and FIGS. 1 and 2, via bottom electrodes 42 are formed within a dielectric material layer (such as lower fourth interconnect-level dielectric material layer 641).

Referring to step 1820 and FIGS. 3, 10, and 13, a layer stack (optionally 52L, 54L, 55L, 56L, 58L) including a phase-change material layer 54L, a thermal protection material layer 55L comprising a thermal protection material having a first thermal conductivity, and a top electrode material layer 56L comprising a top electrode material having a second thermal conductivity may be deposited over the dielectric material layer 641. The second thermal conductivity may be greater than the first thermal conductivity.

In one embodiment, the thermal protection material layer 55L may be formed by depositing a metallic compound material comprising a nitride of a first metal; and the top electrode material layer 56 may be formed by depositing a second metal. In one embodiment, the thermal protection material comprises a doped metal nitride material including dopant atoms; and the first thermal conductivity is lower than a thermal conductivity of an undoped metallic compound comprising all species within the doped metal nitride material less a species of the dopant atoms. In one embodiment, the dopant atoms are selected among atomic elements that provides an increased electrical conductivity for the thermal protection material relative to an electrical conductivity of the undoped metal nitride material. In one embodiment, the thermal protection material comprises dopant atoms selected from B, C, Al, and O.

In one embodiment, the thermal protection material layer 55L may be formed by: depositing an undoped metal nitride layer consisting essentially of an undoped nitride of a first metal; and introducing dopant atoms into the undoped metal nitride layer by implantation. In one embodiment, the thermal protection material layer 55L may be formed by: depositing an undoped metal nitride layer consisting essentially of an undoped nitride of a first metal; and converting the undoped metal nitride layer into a metal oxynitride layer by partial oxidation of the undoped metal nitride layer. In one embodiment, the phase-change material layer 54L may be formed directly on top surfaces of the via bottom electrodes 42.

Referring to step 1830 and FIG. 4-11 and 14-16, the layer stack (optionally 52L, 54L, 55L, 56L, 58L) may be patterned into a plurality of plate stacks (58, 56, 55, 54, optionally 52). Each of the plate stacks (58, 56, 55, 54, optionally 52) comprises a respective phase-change material portion 54, a respective thermal protection plate 55, and a respective top electrode 56, and may be formed over a respective one of the via bottom electrodes 42.

In one embodiment, the layer stack comprises a bottom electrode material layer 52L; the phase-change material layer 54L may be formed on a top surface of the bottom electrode material layer 52L; and each of the plate stacks (58, 56, 55, 54, 52) comprises a respective plate bottom electrode 52 that is a patterned portion of the bottom electrode material layer 52L. Sidewall spacers 57 may be on the plurality of the plate stacks (58, 56, 55, 54, optionally 52). Each of the sidewall spacers is formed on a sidewall of a respective one of the plate stacks (58, 56, 55, 54, optionally 52).

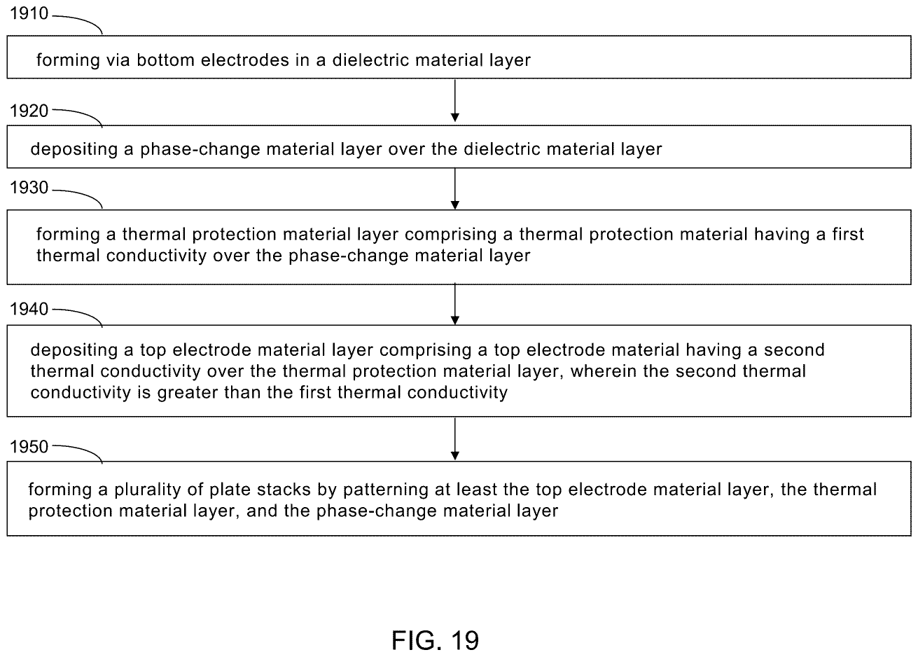

FIG. 19 is a second flowchart that illustrates general processing steps for manufacturing a device structure according to embodiments of the present disclosure. The method may include:

Referring to step 1910 and FIGS. 1 and 2, via bottom electrodes 42 may be formed within a dielectric material layer (such as lower fourth interconnect-level dielectric material layer 641).

Referring to step 1920 and FIGS. 3, 10, and 13, a phase-change material layer 54L may be deposited over the dielectric material layer 641;

Referring to step 1930 and FIGS. 3, 10, and 13, a thermal protection material layer 55L comprising a thermal protection material having a first thermal conductivity may be formed over the phase-change material layer 54L.

Referring to step 1940 and FIGS. 3, 10, and 13, a top electrode material layer 56L comprising a top electrode material having a second thermal conductivity over the thermal protection material layer 55L. The second thermal conductivity is greater than the first thermal conductivity.

Referring to step 1950 and FIG. 4-16, a plurality of plate stacks (58, 56, 55, 54, optionally 52) may be formed by patterning at least the top electrode material layer 56L, the thermal protection material layer 55L, and the phase-change material layer 54L.

In one embodiment, the thermal protection material layer 55L is formed by: depositing a metallic compound material comprising a nitride of a first metal; and implanting dopant atoms into the metallic compound material, wherein the dopant atoms decrease a thermal conductivity of the metallic compound material to the first thermal conductivity. In one embodiment, the dopant atoms comprise a species selected from B, C, Al, and O. In one embodiment, the metallic compound material comprises an undoped metal nitride material consisting of the first metal and nitrogen; and the dopant atoms reduce a thermal conductivity of the undoped metal nitride material to the first thermal conductivity upon incorporation into the undoped metal nitride material. In one embodiment, the dopant atoms (such as carbon atoms) increase an electrical conductivity of the undoped metal nitride material to the first thermal conductivity upon incorporation into the undoped metal nitride material.

Referring to all drawings and according to various embodiments of the present disclosure, a device structure is provided, which comprises: a via bottom electrode 42 located within a dielectric material layer (such as lower fourth interconnect-level dielectric material layer 641); a phase-change material portion 54 overlying the via bottom electrode 42; a thermal protection plate 55 comprising a thermal protection material having a first thermal conductivity; and a top electrode 56 comprising a top electrode material having a second thermal conductivity and overlying the thermal protection plate 55, wherein the second thermal conductivity is greater than the first thermal conductivity.

In one embodiment, the thermal protection material comprises a metallic compound material comprising a nitride of a first metal; and the top electrode material comprises a second metal. In one embodiment, the thermal protection material is a doped metal nitride material including dopant atoms; and the first thermal conductivity is lower than a thermal conductivity of an undoped metallic compound comprising all species within the doped metal nitride material less a species of the dopant atoms.

In one embodiment, the thermal protection material is a doped metal nitride material including dopant atoms; and an electrical conductivity of the thermal protection material is higher than an electrical conductivity of an undoped metallic compound comprising all species within the doped metal nitride material less a species of the dopant atoms. In one embodiment, the thermal protection material comprises dopant atoms selected from B, C, Al, and O.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming via bottom electrodes in a dielectric material layer;
depositing a layer stack including a phase-change material layer, a thermal protection material layer comprising a thermal protection material having a first thermal conductivity, and a top electrode material layer comprising a top electrode material having a second thermal conductivity over the dielectric material layer, wherein the second thermal conductivity is greater than the first thermal conductivity; and
patterning the layer stack into a plurality of plate stacks, wherein each of the plate stacks comprises a respective phase-change material portion, a respective thermal protection plate, and a respective top electrode, and is formed over a respective one of the via bottom electrodes.

2. The method of claim 1, wherein:
the thermal protection material layer is formed by depositing a metallic compound material comprising a nitride of a first metal; and
the top electrode material layer is formed by depositing a second metal.

3. The method of claim 1, wherein:
the thermal protection material comprises a doped metal nitride material including dopant atoms; and
the first thermal conductivity is lower than a thermal conductivity of an undoped metallic compound comprising all species within the doped metal nitride material less a species of the dopant atoms.

4. The method of claim 3, wherein the dopant atoms are selected among atomic elements that provides an increased electrical conductivity for the thermal protection material relative to an electrical conductivity of an undoped metal nitride material.

5. The method of claim 2, wherein the thermal protection material comprises dopant atoms selected from B, C, Al, and O.

6. The method of claim 1, wherein the thermal protection material layer is formed by:
depositing an undoped metal nitride layer consisting essentially of an undoped nitride of a first metal; and
introducing dopant atoms into the undoped metal nitride layer by implantation.

7. The method of claim 1, wherein the thermal protection material layer is formed by:
depositing an undoped metal nitride layer consisting essentially of an undoped nitride of a first metal; and
converting the undoped metal nitride layer into a metal oxynitride layer by partial oxidation of the undoped metal nitride layer.

8. The method of claim 1, wherein:
the layer stack comprises a bottom electrode material layer;
the phase-change material layer is formed on a top surface of the bottom electrode material layer; and
each of the plate stacks comprises a respective plate bottom electrode that is a patterned portion of the bottom electrode material layer.

9. The method of claim 1, further comprising forming sidewall spacers on the plurality of plate stacks, wherein each of the sidewall spacers is formed on a sidewall of a respective one of the plate stacks.

10. The method of claim 1, wherein the phase-change material layer is formed directly on top surfaces of the via bottom electrodes.

11. A method of forming a device structure, comprising:
forming via bottom electrodes in a dielectric material layer;
depositing a phase-change material layer over the dielectric material layer;
forming a thermal protection material layer comprising a thermal protection material having a first thermal conductivity over the phase-change material layer;
depositing a top electrode material layer comprising a top electrode material having a second thermal conductivity over the thermal protection material layer, wherein the second thermal conductivity is greater than the first thermal conductivity; and
forming a plurality of plate stacks by patterning at least the top electrode material layer, the thermal protection material layer, and the phase-change material layer.

12. The method of claim 11, wherein the thermal protection material layer is formed by:
depositing a metallic compound material comprising a nitride of a first metal; and
implanting dopant atoms into the metallic compound material, wherein the dopant atoms decrease a thermal conductivity of the metallic compound material to the first thermal conductivity.

13. The method of claim 12, wherein the dopant atoms comprise a species selected from B, C, Al, and O.

14. The method of claim 12, wherein:
the metallic compound material comprises an undoped metal nitride material consisting of the first metal and nitrogen; and
the dopant atoms reduce a thermal conductivity of the undoped metal nitride material to the first thermal conductivity upon incorporation into the undoped metal nitride material.

15. The method of claim 12, wherein the dopant atoms increase an electrical conductivity of the undoped metal nitride material upon incorporation into an undoped metal nitride material.

16. A device structure comprising:
a via bottom electrode located within a dielectric material layer;
a phase-change material portion overlying the via bottom electrode;
a thermal protection plate comprising a thermal protection material having a first thermal conductivity; and
a top electrode comprising a top electrode material having a second thermal conductivity and overlying the thermal protection plate, wherein the second thermal conductivity is greater than the first thermal conductivity.

17. The device structure of claim 16, wherein:
the thermal protection material comprises a metallic compound material comprising a nitride of a first metal; and
the top electrode material comprises a second metal.

18. The device structure of claim 16, wherein:
the thermal protection material is a doped metal nitride material including dopant atoms; and
the first thermal conductivity is lower than a thermal conductivity of an undoped metallic compound comprising all species within the doped metal nitride material less a species of the dopant atoms.

19. The device structure of claim 16, wherein:
the thermal protection material is a doped metal nitride material including dopant atoms; and
an electrical conductivity of the thermal protection material is higher than an electrical conductivity of an undoped metallic compound comprising all species within the doped metal nitride material less a species of the dopant atoms.

20. The device structure of claim 16, wherein the thermal protection material comprises dopant atoms selected from B, C, Al, and O.
